(19) United States
(12) Patent Application Publication
(10) Pub. No.: US 2025/0266388 A1
(43) Pub. Date: Aug. 21, 2025

(54) SEMICONDUCTOR DEVICE

(71) Applicant: ROHM CO., LTD., Kyoto-shi (JP)

(72) Inventors: Shunya MIKAMI, Kyoto-shi (JP); Yuto NISHIYAMA, Kyoto-shi (JP); Katsutoki SHIRAI, Kyoto-shi (JP)

(21) Appl. No.: 19/200,201

(22) Filed: May 6, 2025

Related U.S. Application Data
(63) Continuation of application No. PCT/JP2023/037552, filed on Oct. 17, 2023.

(30) Foreign Application Priority Data
Nov. 7, 2022 (JP) 2022-178205

(51) Int. Cl. H01L 23/00; H01L 23/31; H01L 23/495

(52) U.S. Cl. CPC H01L 24/48; H01L 23/3107; H01L 23/49562; H01L 24/32; H01L 24/73; H01L 2224/32245; H01L 2224/48175; H01L 2224/48465; H01L 2224/48992; H01L 2224/73265; H01L 2924/13091; H01L 2924/3511

(57) ABSTRACT

A semiconductor device includes: a substrate; a device region provided on the substrate; a terminal covering the device region in a plan view; and at least three pseudo bumps densely arranged in a layout located at vertexes of a triangle in a plan view on the terminal, wherein a extra material is formed by bulging of a part of the terminal from a lower portion to a side portion of each of the three pseudo bumps, a pair of the extra materials of each of the pseudo bumps is formed on both sides of one side and the other side in a first direction of each of the pseudo bumps so as to have directivity along the first direction in a plan view, and the extra materials of the three pseudo bumps are arranged at intervals from each other along a second direction.

### CROSS REFERENCE TO RELATED APPLICATIONS

The present application is a bypass continuation application of International Patent Application No. PCT/JP2023/037552, filed on Oct. 17, 2023, which corresponds to Japanese Patent Application No. 2022-178205 filed on Nov. 7, 2022 with the Japan Patent Office, and the entire disclosure of this application is incorporated herein by reference.

### TECHNICAL FIELD

The present disclosure relates to a semiconductor device.

### BACKGROUND ART

Patent Literature 1 (WO 2012-005073 A1) discloses a semiconductor device including an electrode for wire bonding formed in the vicinity of an active element such as a microcomputer or a power transistor.

### BRIEF DESCRIPTION OF DRAWINGS

FIG. 1 is a plan view illustrating a semiconductor chip according to a first configuration example.

FIG. 2 is a cross-sectional view taken along line II-II illustrated in FIG. 1.

FIG. 3 is a circuit diagram illustrating an electrical configuration example of the semiconductor chip illustrated in FIG. 1.

FIG. 4 is a plan view illustrating a layout of an output region.

FIG. 5 is a cross-sectional view taken along line V-V illustrated in FIG. 4.

FIG. 6 is a cross-sectional view taken along line VI-VI illustrated in FIG. 4.

FIG. 7 is a cross-sectional view taken along line VII-VII illustrated in FIG. 4.

FIG. 8 is a perspective view illustrating a semiconductor device on which the semiconductor chip illustrated in FIG. 1 is mounted.

FIG. 9 is a plan view illustrating an internal structure of the semiconductor device illustrated in FIG. 8.

FIG. 10 is a cross-sectional view taken along line X-X illustrated in FIG. 9.

FIG. 11 is a cross-sectional view taken along line XI-XI illustrated in FIG. 9.

FIG. 12 is an enlarged plan view illustrating a part of FIG. 9.

FIG. 13 is a cross-sectional view taken along line XIII-XIII illustrated in FIG. 12.

FIG. 14 is a cross-sectional view taken along line XIV-XIV illustrated in FIG. 12.

FIG. 15A is an enlarged view of a portion surrounded by an alternate long and two short dashed line XV in FIG. 13.

FIG. 15B is a cross-sectional view of a pseudo bump cut along a second direction.

FIG. 16 is a bonding method diagram of the pseudo bump to a terminal.

FIG. 17 is an enlarged view of the pseudo bump in a plan view.

FIG. 18 is a plan view illustrating a first layout of the pseudo bump.

FIG. 19 is a plan view illustrating a second layout of the pseudo bump.

FIG. 20 is a plan view illustrating a modified example of the layout in FIG. 12.

FIG. 21 is a plan view illustrating a semiconductor chip according to a second configuration example.

### DESCRIPTION OF EMBODIMENTS

First, preferred embodiments of the present disclosure will be described in detail with reference to the accompanying drawings. The attached drawings are not drawn precisely but are schematic views and are not necessarily matched in scale, etc. Also, identical reference signs are given to corresponding structures among the accompanying drawings, and duplicate descriptions thereof shall be omitted or simplified. For structures where the description is omitted or simplified, the description given before the omission or simplification applies.

When a term such as “substantially equal” is used in the description in which the comparison target exists, the term includes a numerical value (form) equal to the numerical value (form) of the comparison target and also includes a numerical error (form error) in a range of +10% based on the numerical value (form) of the comparison target. In the preferred embodiment, terms such as “first,” “second,” and “third” are used, but these are symbols attached to the names of the respective structures in order to clarify the description order, and are not attached to limit the names of the respective structures.

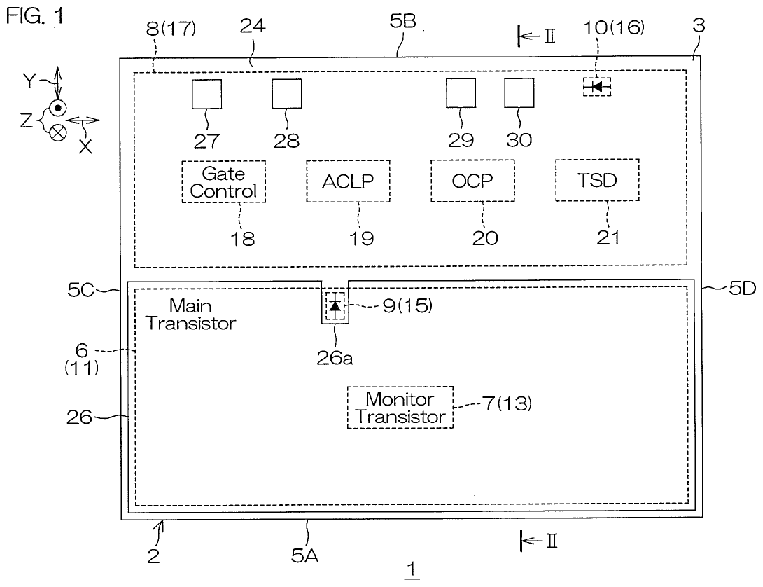

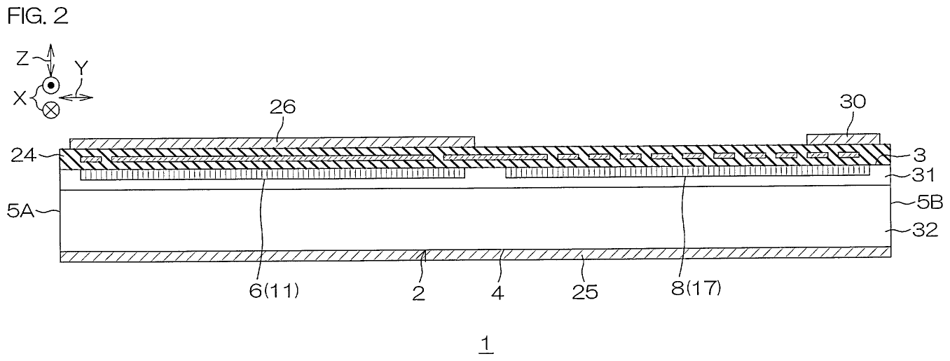

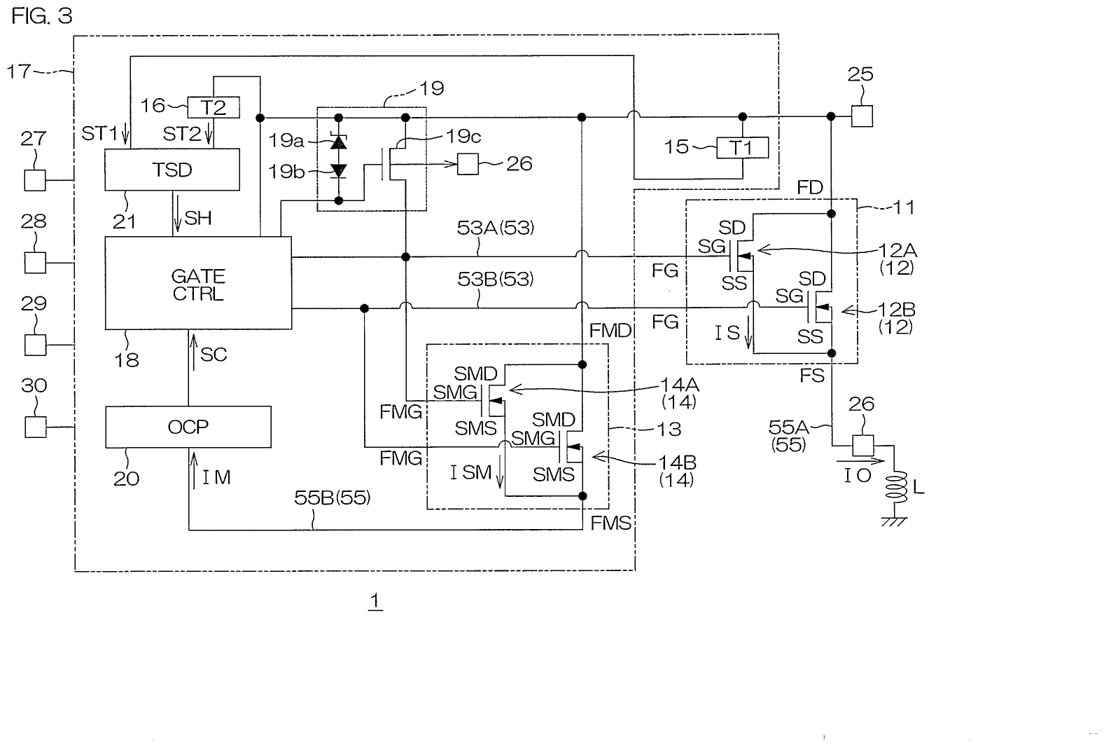

FIG. 1 is a plan view illustrating a semiconductor chip 1. FIG. 2 is a cross-sectional view taken along line II-II illustrated in FIG. 1. FIG. 3 is a circuit diagram illustrating an electrical configuration example of the semiconductor chip 1 illustrated in FIG. 1. FIG. 3 illustrates an example in which an inductive load L is connected to an output terminal (source terminal 26).

Referring to FIGS. 1 and 2, the semiconductor chip 1 includes a substrate 2 formed in a rectangular parallelepiped shape in this embodiment. The substrate 2 is formed as an Si single crystal substrate. The substrate 2 may be made of a wide band gap semiconductor single crystal substrate (for example, SiC single crystal substrate). The substrate 2 has a first principal surface 3 on one side, a second principal surface 4 on the other side, and first to fourth side surfaces 5A to 5D connecting the first principal surface 3 and the second principal surface 4.

The first principal surface 3 and the second principal surface 4 are formed in a quadrangular shape in a plan view (hereinafter, simply referred to as “plan view”) viewed from a normal direction Z. The first principal surface 3 is a device surface on which a functional device is formed. The second principal surface 4 is a non-device surface. The first side surface 5A and the second side surface 5B extend in a first direction X along the first principal surface 3 and face a second direction Y intersecting (specifically, orthogonal to) the first direction X. The third side surface 5C and the fourth side surface 5D extend in the second direction Y and face each other in the first direction X.

Each of the first to fourth side surfaces 5A to 5D may have a length of 0.1 mm or more and 10 mm or less in a plan view. The lengths of the first to fourth side surfaces 5A to 5D may be 0.1 mm or more and 0.5 mm or less, 0.5 mm or more and 1 mm or less, 1 mm or more and 2.5 mm or less, 2.5 mm or more and 5 mm or less, 5 mm or more and 7.5 mm or less, or 7.5 mm or more and 10 mm or less.

The semiconductor chip 1 includes an output region 6, a current detecting region 7, a control region 8, a first temperature detecting region 9, and a second temperature detecting region 10 provided on the first principal surface 3. The output region 6, the current detecting region 7, the control region 8, the first temperature detecting region 9, and the second temperature detecting region 10 may be referred to as a “first device region,” a “second device region,” a “third device region,” a “fourth device region,” and a “fifth device region,” respectively.

The output region 6 is a region having a functional device arranged to generate an output signal to be output to the outside (outside the semiconductor chip 1). In this embodiment, the output region 6 is partitioned into an L shape in a plan view. Specifically, the output region 6 includes a first region 6A extending in a band shape along the first direction X in a region on the first side surface 5A side, and a second region 6B extending in a band shape along the second direction Y in a region on the third side surface 5C side. The output region 6 is partitioned into regions on the first side surface 5A side in the first principal surface 3. The output region 6 may be partitioned into a quadrangular shape in a plan view, or may be partitioned into a polygonal shape other than the quadrangular shape. The position, size, and planar shape of the output region 6 are arbitrary, and are not limited to a specific form.

The current detecting region 7 is a region having a functional device configured to generate a monitor signal for monitoring an output signal. The current detecting region 7 is preferably adjacent to the output region 6. In this embodiment, the current detecting region 7 has a planar area smaller than the planar area of the output region 6, and is provided inside the output region 6.

That is, the current detecting region 7 is provided so as to be surrounded by the output region 6. The term “surrounded” as used herein includes a form in which the current detecting region 7 is surrounded by the output region 6 over the entire circumference, and also includes a form in which the current detecting region 7 is adjacent to the output region 6 in at least two directions. The functional device of the current detecting region 7 is, in this embodiment, formed utilizing a part of the functional device of the output region 6.

The control region 8 is a region having a plurality of types of functional devices configured to generate control signals for controlling the functional devices of the output region 6. In this embodiment, the control region 8 is partitioned into a region on the second side surface 5B side with respect to the output region 6, and faces the output region 6 in the second direction Y. The control region 8 may be partitioned into a quadrangular shape in a plan view, or may be partitioned into a polygonal shape other than the quadrangular shape. The position, size, and planar shape of the control region 8 are arbitrary, and are not limited to a specific form.

The control region 8 preferably has a planar area equal to or smaller than the planar area of the output region 6. The area ratio of the planar area of the control region 8 to the planar area of the output region 6 may be 0.1 or more and 2 or less. The area ratio of the planar area of the control region 8 to the planar area of the output region 6 may be 0.1 or more and 0.25 or less, 0.25 or more and 0.5 or less, 0.5 or more and 0.75 or less, 0.75 or more and 1 or less, 1 or more and 1.25 or less, 1.25 or more and 1.5 or less, 1.5 or more and 1.75 or less, or 1.75 or more and 2 or less. The area ratio is preferably smaller than 1.

The first temperature detecting region 9 is a region having a functional device configured to generate a temperature detecting signal for monitoring the temperature of the output region 6. The first temperature detecting region 9 is preferably adjacent to the output region 6. The first temperature detecting region 9 has a planar area smaller than the planar area of the output region 6, and is provided inside the output region 6.

That is, the first temperature detecting region 9 is surrounded by the output region 6. The term “surrounded” as used herein includes a form in which the first temperature detecting region 9 is surrounded by the output region 6 over the entire circumference, and also includes a form in which the first temperature detecting region 9 is adjacent to the output region 6 in at least two directions.

The second temperature detecting region 10 is a region having a functional device configured to generate a temperature detecting signal for monitoring the temperature of the control region 8. The second temperature detecting region 10 is preferably adjacent to the control region 8. In this embodiment, the second temperature detecting region 10 has a planar area smaller than the planar area of the control region 8, and is provided inside the control region 8.

That is, the second temperature detecting region 10 is surrounded by the control region 8. The term “surrounded” as used herein includes a form in which the second temperature detecting region 10 is surrounded by the control region 8 over the entire circumference, and also includes a form in which the second temperature detecting region 10 is adjacent to the control region 8 in at least two directions.

Referring to FIGS. 1 and 3, the semiconductor chip 1 includes an n-system insulated gate type main transistor 11 formed in the output region 6. “n” is 2 or more (n≥2). In FIG. 3, two systems of main transistors 11 are illustrated. The main transistor 11 may be referred to as a “gate dividing transistor.” The main transistor 11 includes n (n-number) first gates FG, one first drain FD, and one first source FS.

The main transistor 11 is configured such that the same or different n gate signals (gate voltages) are input to the n first gates FG at arbitrary timing. Each gate signal includes an ON signal for controlling a part of the main transistor 11 to an on state and an OFF signal for controlling a part of the main transistor 11 to an off state.

The main transistor 11 generates a single output current IO (output signal) in response to the n gate signals. That is, the main transistor 11 is formed as a multi-input single-output type switching device. The output current IO is a drain-source current flowing between the first drain FD and the first source FS. The output current IO is output to the outside of the substrate 2.

The main transistor 11 includes n-system transistors 12. In FIG. 3, a first-system transistor 12A and a second-system transistor 12B are illustrated. The n-system transistors 12 are collectively formed in a single output region 6, and are configured to be controlled to an on state and an off state electrically independently of each other.

Specifically, the n-system transistors 12 are connected in parallel to each other such that the n gate signals are individually input. That is, the n-system main transistor 11 is configured such that the system transistor 12 in an on state and the system transistor 12 in an off state coexist at arbitrary timing.

The n-system transistors 12 each include a second gate SG, a second drain SD, and a second source SS. The n second gates SG constitute n first gates FG, respectively. The n second drains SD constitute one first drain FD. The n second sources SS constitute one first source FS. The n-system transistors 12 each generate a system current IS in response to the corresponding gate signal. The system current IS is a drain-source current flowing between the second drain SD and the second source SS of the system transistor 12. The n-system currents IS may have values different from each other or values equal to each other. The n-system currents IS are added between the first drain FD and the first source FS. Thereby, a single output current IO including an addition value of the n-system currents IS is generated.

Referring to FIGS. 1 and 3, the semiconductor chip 1 includes an m-system insulated gate monitor transistor 13 formed in the current detecting region 7. “m” is 1 or more (m≥1). FIG. 3 illustrates two systems of monitor transistors 13. The monitor transistor 13 is connected in parallel to the main transistor 11, and is configured to monitor a part or all of output current IO. That is, the monitor transistor 13 is connected in parallel to at least one system transistor 12 and monitors at least one system current IS.

The monitor transistor 13 is preferably connected in parallel to the plurality of system transistors 12 and configured to monitor the plurality of system currents IS. In this embodiment, the monitor transistor 13 includes n-system (m=n) monitor transistors 13 connected in parallel to the n-system transistors 12 so as to monitor the n-system currents IS. In the following description, “m-system” is replaced with “n-system” and “m” is replaced with “n” as necessary.

In this embodiment, the monitor transistor 13 includes n first monitor gates FMG, one first monitor drain FMD, and one first monitor source FMS. The n first monitor gates FMG are configured such that n monitor gate signals (monitor gate voltages) are individually input.

The first monitor drain FMD is electrically connected to the first drain FD. The first monitor source FMS is electrically separated from the first source FS. The same or different n monitor gate signals are input to the n first monitor gates FMG at arbitrary timing. Each monitor gate signal includes an ON signal for controlling a part of a monitor transistor 13 to an on state and an OFF signal for controlling a part of a monitor transistor 13 to an off state.

In this embodiment, the monitor transistor 13 generates a single monitor current IM (monitor signal) for monitoring the n-system currents IS (output currents IO) in response to the n monitor gate signals. That is, the monitor transistor 13 is formed as a multi-input single-output type switching device. The monitor current IM is a drain-source current flowing between the first monitor drain FMD and the first monitor source FMS.

In this embodiment, the n first monitor gates FMG are electrically connected to the corresponding n first gates FG in a one-to-one correspondence relationship. Therefore, the n first monitor gates FMG are configured such that monitor gate signals including gate signals are individually input. That is, the monitor transistor 13 is controlled to be turned on and off at the same timing as the main transistor 11, and generates the monitor current IM that increases and decreases in conjunction with the increase and decrease of the output current IO.

The monitor current IM is output to the outside of the output region 6 via a current path electrically independent of the current path of the output current IO. The monitor current IM is equal to or smaller than the output current IO (IM≤IO). The monitor current IM is preferably smaller than the output current IO (IM<IO). The current ratio IM/IO of the monitor current IM to the output current IO is arbitrary. The current ratio IM/IO may be 1/10000 or more and 1 or less (preferably smaller than 1).

The monitor transistor 13 includes m (n in this embodiment) system monitor transistors 14. FIG. 3 illustrates a first-system monitor transistor 14A and second-system monitor transistor 14B. The number of systems of the monitor transistor 13 is adjusted by the number of system monitor transistors 14.

That is, when the m-system monitor transistor 13 monitors at least one system current IS, the at least one system monitor transistor 14 is electrically connected (specifically, connected in parallel) to the at least one system transistor 12. When the m-system monitor transistors 13 monitors the plurality of system currents IS, the plurality of system monitor transistors 14 are electrically connected to the plurality of system transistors 12. In this embodiment, the n-system monitor transistors 14 are electrically connected to the n-system transistors 12.

The n-system monitor transistors 14 are configured to be controlled to an on state and an off state electrically independently of each other. Specifically, the n-system monitor transistors 14 are connected in parallel to each other such that the n monitor gate signals are individually input. That is, the monitor transistor 13 is configured such that the system monitor transistor 14 in an on state and the system monitor transistor 14 in an off state coexist at arbitrary timing.

The n-system monitor transistors 14 include a second monitor gate SMG, a second monitor drain SMD, and a second monitor source SMS, respectively. The n second monitor gates SMG constitute n first monitor gates FMG, respectively. The n second monitor drains SMD constitute one first monitor drain FMD. The n second monitor sources SMS constitute one first monitor source FMS.

The same or different n monitor gate signals are input to the n second monitor gates SMG at arbitrary timing. In response to the corresponding monitor gate signal, the n-system monitor transistors 14 each generate a system monitor current ISM (system monitor signal) for monitoring the system current IS of the corresponding system transistor 12.

The system monitor current ISM is a drain-source current flowing between the second monitor drain SMD and the second monitor source SMS of the system monitor transistor 14. The n-system monitor currents ISM are added between the first monitor drain FMD and the first monitor source FMS. Thereby, a single monitor current IM including an addition value of the n-system monitor currents ISM is generated.

In this embodiment, the n-system monitor transistors 14 are electrically connected to the corresponding system transistors 12 in a one-to-one correspondence relationship, and are controlled in conjunction with the corresponding system transistors 12. Specifically, the n-system monitor transistors 14 are connected in parallel to the corresponding system transistors 12 such that the system monitor current ISM is output to a current path electrically independent from the current path of the system current IS.

The n second monitor gates SMG are electrically connected to the corresponding first gates FG in a one-to-one correspondence relationship. That is, in this embodiment, the monitor gate signal including the gate signal is input to each of the n second monitor gates SMG. The second monitor drain SMD is electrically connected to the first drain FD. The second monitor source SMS is electrically separated from the first source FS.

Thereby, the n-system monitor transistors 14 are controlled to be turned on and off at the same timing as the corresponding system transistors 12, and each generate the system monitor current ISM that increases and decreases in conjunction with the increase and decrease of the corresponding system current IS. The system monitor current ISM is extracted from the second monitor source SMS electrically independent of the system current IS.

Each system monitor current ISM is equal to or smaller than the corresponding system current IS (ISM≤IS). Each system monitor current ISM is preferably smaller than the corresponding system current IS (ISM<IS). The current ratio ISM/IS of the system monitor current ISM to the system current IS is arbitrary. The current ratio ISM/IS may be 1/10000 or more and 1 or less (preferably smaller than 1).

Hereinafter, control examples of the two-system main transistor 11 and the two-system monitor transistor 13 will be described. When the gate signal (that is, the OFF signal) smaller than the gate threshold voltage is input to all of the n first gates FG, the first-system transistor 12A and the second-system transistor 12B are turned off. This control is applied when the main transistor 11 is turned off. On the other hand, in the monitor transistor 13, the first-system monitor transistor 14A and the second-system monitor transistor 14B are turned off in conjunction with the main transistor 11.

When a gate signal (that is, an ON signal) equal to or higher than the gate threshold voltage is input to all of the n first gates FG, the first-system transistor 12A and the second-system transistor 12B are turned on. Thereby, the main transistor 11 generates the output current IO including the system current IS of the first-system transistor 12A and the system current IS of the second-system transistor 12B. In this case, the channel utilization rate of the main transistor 11 relatively increases, and the on-resistance relatively decreases. This control is applied during normal operation of the main transistor 11.

On the other hand, in the monitor transistor 13, the first-system monitor transistor 14A and the second-system monitor transistor 14B are turned on in conjunction with the main transistor 11. The monitor transistor 13 generates the monitor current IM including the system monitor current ISM of the first-system monitor transistor 14A and the system monitor current ISM of the second-system monitor transistor 14B. In this case, the channel utilization rate of the monitor transistor 13 relatively increases, and the on-resistance relatively decreases.

When a gate signal (that is, an ON signal) equal to or higher than the gate threshold voltage is input to the first gate FG of the first-system transistor 12A and a gate signal (that is, an OFF signal) lower than the gate threshold voltage is input to the first gate FG of the second-system monitor transistor 14B, the first-system transistor 12A is turned on, and the second-system monitor transistor 14B is turned off.

Thereby, the main transistor 11 generates the output current IO including the system current IS of the first-system transistor 12A. In this case, the channel utilization rate of the main transistor 11 relatively decreases, and the on-resistance relatively increases. This control is applied at the time of active clamping operation of the main transistor 11.

On the other hand, in the monitor transistor 13, the first-system monitor transistor 14A is turned on and the second-system monitor transistor 14B is turned off in conjunction with the main transistor 11. The monitor transistor 13 generates the monitor current IM including the system monitor current ISM of the first-system monitor transistor 14A. In this case, the channel utilization rate of the monitor transistor 13 relatively decreases, and the on-resistance relatively increases.

Referring to FIGS. 1 and 3, the semiconductor chip 1 includes a first temperature-sensitive diode 15 as an example of a first temperature sensor formed in the first temperature detecting region 9. The first temperature-sensitive diode 15 has a temperature characteristic that varies according to the temperature T1 of the output region 6 with respect to the forward voltage, and generates a first temperature detecting signal ST1 that detects the temperature of the output region 6. The forward voltage may have a negative temperature characteristic that linearly decreases as the temperature of the output region 6 rises.

Referring to FIGS. 1 and 3, the semiconductor chip 1 includes a second temperature-sensitive diode 16 as an example of a second temperature sensor formed in the second temperature detecting region 10. The second temperature-sensitive diode 16 has a temperature characteristic that varies according to the temperature T2 of the control region 8 with respect to the forward voltage, and generates a second temperature detecting signal ST2 that detects the temperature of the control region 8. The forward voltage may have a negative temperature characteristic that linearly decreases as the temperature of the control region 8 rises.

The second temperature-sensitive diode 16 preferably has substantially the same configuration as the first temperature-sensitive diode 15, and preferably has substantially the same electrical characteristics as the first temperature-sensitive diode 15. When the main transistor 11 is generating the output current IO, the temperature T2 of the control region 8 is lower than the temperature TI of the output region 6 (T2<T1). Therefore, at the time of generating the output current IO, the forward voltage of the second temperature-sensitive diode 16 is larger than the forward voltage of the first temperature-sensitive diode 15.

The semiconductor chip 1 includes a control circuit 17 formed in the control region 8. The control circuit 17 may be referred to as a “control integrated circuit (IC).” The control circuit 17 constitutes an intelligent power device (IPD) together with the main transistor 11. The IPD may be referred to as an “intelligent power module (IPM).” The control circuit 17 includes a plurality of types of functional circuits that implement various functions in response to an electric signal input from the outside.

The control circuit 17 includes, in this embodiment, a gate driving circuit 18, an active clamp circuit 19, an overcurrent protection circuit 20, and a thermal shutdown circuit 21. The overcurrent protection circuit 20 may be referred to as an “over current protection (OCP) circuit,” and the thermal shutdown circuit 21 may be referred to as a “thermal shutdown (TSD) circuit.” The monitor transistor 13, the first temperature-sensitive diode 15, and the second temperature-sensitive diode 16 described above constitute a part of the control circuit 17.

The gate driving circuit 18 is electrically connected to the first gate FG of the main transistor 11 and the first monitor gate FMG of the monitor transistor 13, and generates a gate signal for controlling the main transistor 11 and the monitor transistor 13 in response to an electrical signal from the outside.

The active clamp circuit 19 is electrically connected to the main transistor 11 and the gate driving circuit 18. Specifically, the active clamp circuit 19 is electrically connected to some (not all) of the first gate FG, the first drain FD, and the gate driving circuit 18.

The active clamp circuit 19 may include a first diode stage 19a, a second diode stage 19b, and an n-channel type MISFET 19c. The first diode stage 19a includes one or more Zener diodes forming a forward series circuit. The cathode of the first diode stage 19a is electrically connected to the first drain FD.

The second diode stage 19b includes one or more pn junction diodes forming a forward series circuit. The anode of the second diode stage 19b is reverse-biased to the anode of the first diode stage 19a. The cathode of the second diode stage 19b is electrically connected to the gate driving circuit 18.

The gate of the MISFET 19c is electrically connected to the cathode of the second diode stage 19b. The back gate of the MISFET 19c is electrically connected to the first source FS. The drain of the MISFET 19c is connected to the first drain FD. A source of the MISFET 19c is electrically connected to a part (not all) of the first gate FG.

The active clamp circuit 19 limits (clamps) an output voltage in cooperation with the gate driving circuit 18 when a counter electromotive force is input to the main transistor 11 due to energy accumulated in the inductive load L, and protects the main transistor 11 from the counter electromotive force. That is, the active clamp circuit 19 is configured to limit the output voltage until the counter electromotive force is consumed by causing the main transistor 11 to perform active clamp operation when the counter electromotive force is input.

Specifically, the active clamp circuit 19 controls a part of the main transistor 11 (for example, the first-system transistor 12A) to be in an on state and controls a part of the main transistor 11 (for example, the second-system transistor 12B) to be in an off state in cooperation with the gate driving circuit 18 during the active clamp operation.

Also, the active clamp circuit 19 controls a part of the monitor transistor 13 (for example, the first-system monitor transistor 14A) to be in an on state and controls a part of the monitor transistor 13 (for example, the second-system monitor transistor 14B) to be in an off state in cooperation with the gate driving circuit 18 during the active clamp operation.

The active clamp circuit 19 may be configured to perform on/off control of the n-system transistors 12 (system monitor transistors 14) when the first source FS of the main transistor 11 becomes equal to or lower than a predetermined voltage (for example, a predetermined negative voltage).

The overcurrent protection circuit 20 is electrically connected to the monitor transistor 13 and the gate driving circuit 18. The overcurrent protection circuit 20 is electrically connected to the first monitor source FMS of the monitor transistor 13, and is configured to receive a part or all (all in this embodiment) of the monitor current IM. The overcurrent protection circuit 20 controls the gate signal in cooperation with the gate driving circuit 18 to protect the main transistor 11 from the overcurrent.

The overcurrent protection circuit 20 may be configured to generate the overcurrent detecting signal SC and output the overcurrent detecting signal C to the gate driving circuit 18 when the monitor current IM exceeds a predetermined threshold. The overcurrent detecting signal SC is a signal for limiting a part or all of the n gate signals generated in the gate driving circuit 18 to a predetermined value or less (for example, an off state).

The gate driving circuit 18 limits a part or all of the n gate signals in response to the overcurrent detecting signal SC, and suppresses the overcurrent flowing through the main transistor 11. When the monitor current IM becomes equal to or smaller than the predetermined threshold value, the overcurrent protection circuit 20 shifts the gate driving circuit 18 (main transistor 11) to the normal control.

The thermal shutdown circuit 21 is electrically connected to the first temperature-sensitive diode 15, the second temperature-sensitive diode 16, and the gate driving circuit 18. The thermal shutdown circuit 21 is configured to control the gate signal in cooperation with the gate driving circuit 18 to protect the main transistor 11 from overheating. The first temperature detecting signal ST1 is input from the first temperature-sensitive diode 15 to the thermal shutdown circuit, and the second temperature detecting signal ST2 is input from the second temperature-sensitive diode 16 to the thermal shutdown circuit 21.

The thermal shutdown circuit 21 may be configured to generate the overheat detecting signal SH and output the overheat detecting signal SH to the gate driving circuit 18 when a difference value between the first temperature detecting signal ST1 and the second temperature detecting signal ST2 exceeds a predetermined threshold value. The overheat detecting signal SH is a signal for limiting a part or all of the n gate signals generated in the gate driving circuit 18 to be in an off state.

The gate driving circuit 18 controls a part or all of the main transistor 11 to be in an off state in response to the overheat detecting signal SH, and suppresses a temperature rise in the output region 6. Also, the gate driving circuit 18 controls a part or all of the monitor transistor 13 to be in an off state in response to the overheat detecting signal SH, and suppresses a temperature rise of the current detecting region 7 (output region 6). When the difference value becomes equal to or smaller than the threshold value, the thermal shutdown circuit 21 shifts the gate driving circuit 18 to the normal control.

Referring to FIG. 2, the semiconductor chip 1 includes an interlayer insulating film 24 covering the first principal surface 3. The interlayer insulating film 24 collectively covers the output region 6, the current detecting region 7, the control region 8, the first temperature detecting region 9, and the second temperature detecting region 10. In this embodiment, the interlayer insulating film 24 has a multilayer wiring structure including a plurality of insulating films laminated on the first principal surface 3 and a plurality of wirings arranged on an arbitrary insulating film.

Each insulating film may include at least one of a silicon oxide film and a silicon nitride film. Each wiring may include at least one of a pure Al layer (Al layer having a purity of 99% or more), a Cu layer (Cu layer having a purity of 99% or more), an AlCu alloy layer, an AlSiCu alloy layer, and an AlSi alloy layer.

Referring to FIGS. 1 and 2, the semiconductor chip 1 includes a plurality of terminals 25 to 30. The number, layout, and the like of the plurality of terminals 25 to 30 are appropriately adjusted according to the specifications of the main transistor 11 and the specifications of the control circuit 17. In this embodiment, the plurality of terminals 25 to 30 include a drain terminal 25 (power supply terminal), a source terminal 26 (output terminal), a first control terminal 27, a second control terminal 28, a third control terminal 29, and a fourth control terminal 30.

The drain terminal 25 covers the second principal surface 4 of the substrate 2 and is electrically connected to the second principal surface 4. The drain terminal 25 may include at least one of a Ti layer, an Ni layer, an Au layer, an Ag layer, and an Al layer. The drain terminal 25 may have a laminated structure in which at least two of a Ti layer, an Ni layer, an Au layer, an Ag layer, and an Al layer are laminated in an arbitrary form. The drain terminal 25 is electrically connected to the first drain FD of the main transistor 11 and transmits a power supply potential.

The source terminal 26 is disposed on the interlayer insulating film 24. The source terminal 26 covers the output region 6 so as to expose the control region 8 in a plan view. The layout of the source terminal 26 is adjusted by the layout of the output region 6, and is not limited to a specific form. In this embodiment, the source terminal 26 is formed in a quadrangular shape (specifically, a rectangular shape extending in the first direction X) in a plan view. As a matter of course, the source terminal 26 may be formed in a polygonal shape other than a quadrangular shape in a plan view.

In this embodiment, the source terminal 26 has a cutout portion 26a cut out in a quadrangular shape so as to expose the first temperature detecting region 9 (first temperature-sensitive diode 15). The source terminal 26 is electrically connected to the first source FS of the main transistor 11, and transmits the output current IO to the outside. The source terminal 26 may include one or both of an Al-based metal layer and a Cu-based metal layer. The source terminal 26 may include at least one of a pure Al layer, a pure Cu layer, an AlCu alloy layer, an AlSiCu alloy layer, or an AlSi alloy layer.

The first to fourth control terminals 27 to 30 are arranged on the interlayer insulating film 24. The first to fourth control terminals 27 to 30 may be, for example, an input terminal that gives an input signal to the control circuit 17, an enable terminal that gives an enable signal to the control circuit 17, a self-diagnosis output terminal that outputs an electric signal for diagnosing the state of the control circuit 17, and a ground terminal that gives a ground potential to the control circuit 17.

The first to fourth control terminals 27 to 30 cover a region (specifically, the control region 8) outside the output region 6 in a plan view. Each of the first to fourth control terminals 27 to 30 has a planar area smaller than the planar area of the source terminal 26. The first to fourth control terminals 27 to 30 may include at least one of a pure Al layer, a pure Cu layer, an AlCu alloy layer, an AlSiCu alloy layer, and an AlSi alloy layer.

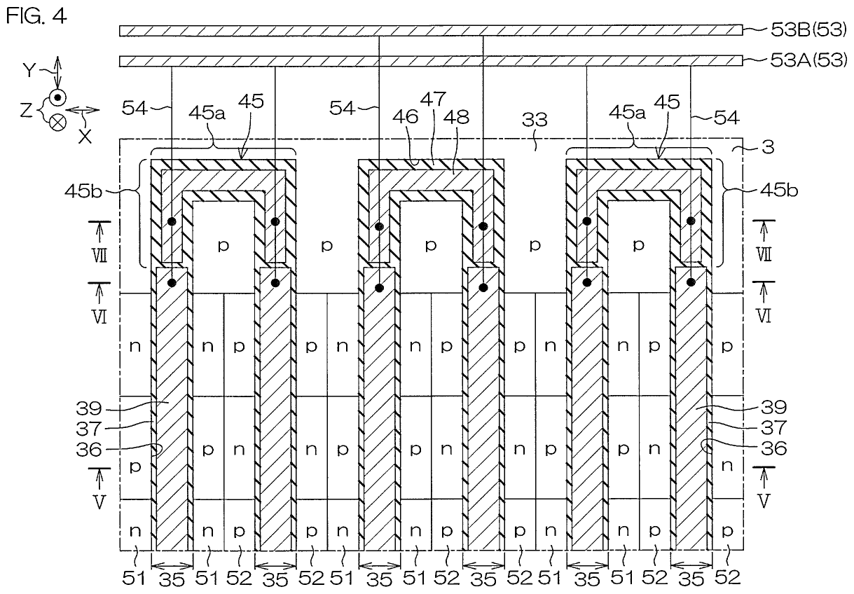

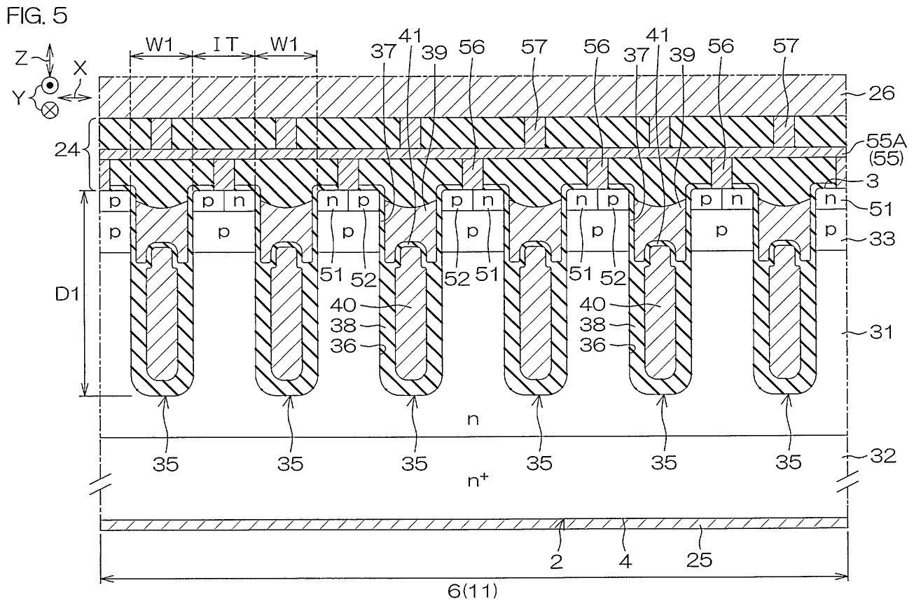

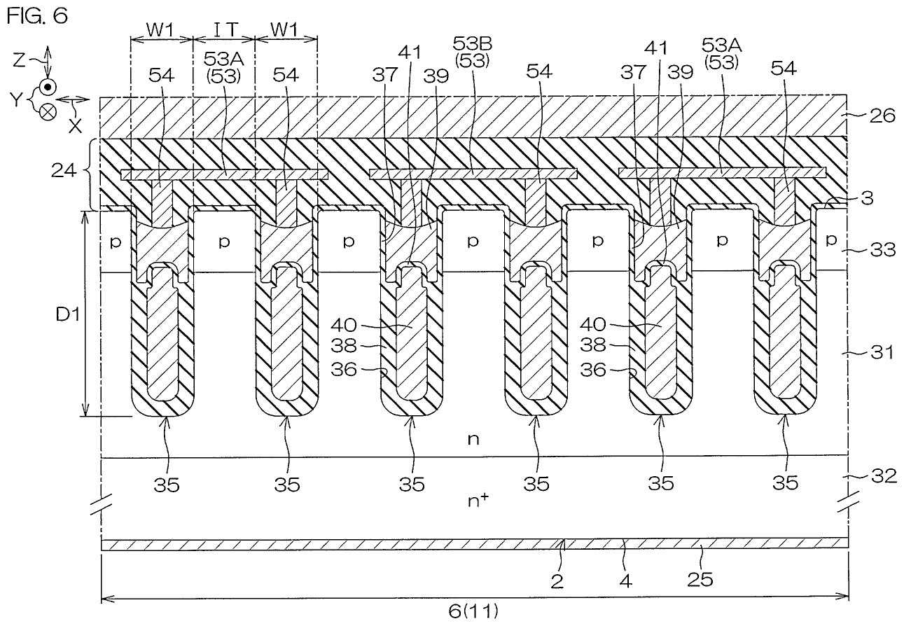

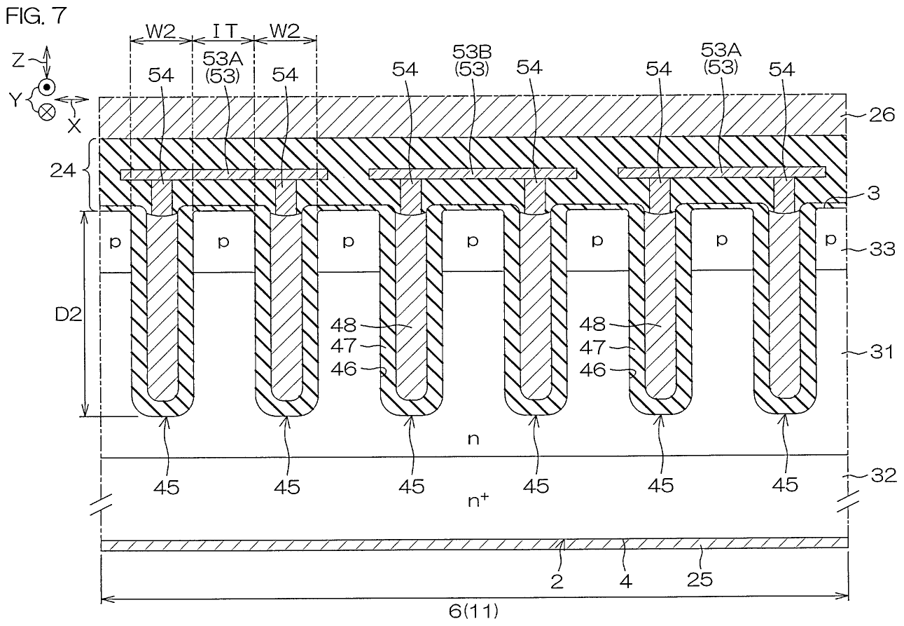

Hereinafter, the configuration of the output region 6 will be described with reference to FIGS. 4 to 7. FIG. 4 is a plan view illustrating a layout of the output region 6. FIG. 5 is a cross-sectional view taken along line V-V illustrated in FIG. 4. FIG. 6 is a cross-sectional view taken along line VI-VI illustrated in FIG. 4. FIG. 7 is a cross-sectional view taken along line VII-VII illustrated in FIG. 4.

The semiconductor chip 1 includes an n-type (first conductivity type) first semiconductor region 31 formed in a surface layer portion of the first principal surface 3 of the substrate 2. The first semiconductor region 31 forms a first drain FD of the main transistor 11 and a first monitor drain FMD of the monitor transistor 13. The first semiconductor region 31 may be referred to as a “drift region.”

The first semiconductor region 31 is formed over the entire surface layer portion of the first principal surface 3 and is exposed from the first principal surface 3 and the first to fourth side surfaces 5A to 5D. The thickness of the first semiconductor region 31 may be 5 μm or more and 30 μm or less. The thickness of the first semiconductor region 31 is preferably 10 μm or more and 20 μm or less. In this embodiment, the first semiconductor region 31 is formed by an n-type epitaxial layer (Si epitaxial layer).

The semiconductor chip 1 includes an n-type second semiconductor region 32 formed in a surface layer portion of the second principal surface 4 of the substrate 2. The second semiconductor region 32 forms the first drain FD of the main transistor 11 and the first monitor drain FMD of the monitor transistor 13 together with the first semiconductor region 31. The second semiconductor region 32 may be referred to as a “drain region.”

The second semiconductor region 32 is formed over the entire surface layer portion of the second principal surface 4 so as to be electrically connected to the first semiconductor region 31, and is exposed from the second principal surface 4 and the first to fourth side surfaces 5A to 5D. The second semiconductor region 32 is thicker than the first semiconductor region 31. The thickness of the second semiconductor region 32 may be 10 μm or more and 450 μm or less. The thickness of the second semiconductor region 32 is preferably 50 μm or more and 150 μm or less. In this embodiment, the second semiconductor region 32 is formed as an n-type semiconductor substrate (Si semiconductor substrate).

The semiconductor chip 1 includes a p-type (second conductivity type) body region 33 formed in a surface layer portion of the first semiconductor region 31 of the output region 6 and the current detecting region 7. The body region 33 is formed with a space from the bottom portion of the first semiconductor region 31 toward the first principal surface 3 side, and faces the second semiconductor region 32 with a part of the first semiconductor region 31 interposed therebetween.

The semiconductor chip 1 includes a plurality of trench structures 35 formed on the first principal surface 3 in the output region 6. The trench structure 35 may be referred to as a “trench gate structure.” The plurality of trench structures 35 include a plurality of trench structures 35 for the main transistor 11 formed in the output region 6 and a plurality of trench structures 35 for the monitor transistor 13 formed in the current detecting region 7. The number of the plurality of trench structures 35 for the monitor transistor 13 is smaller than the number of the plurality of trench structures 35 for the main transistor 11.

The plurality of trench structures 35 are arranged at intervals in the first direction X in a plan view, and are each formed in a band shape extending in the second direction Y. The plurality of trench structures 35 penetrate the body region 33 so as to reach the first semiconductor region 31. The plurality of trench structures 35 are formed at intervals from the bottom portion of the first semiconductor region 31 toward the first principal surface 3 side, and face the second semiconductor region 32 with a part of the first semiconductor region 31 interposed therebetween.

Each trench structure 35 has a first width W1 and a first depth D1. The first width W1 is a width in a direction orthogonal to the direction in which the trench structure 35 extends. The first width W1 may be 0.5 μm or more and 2 μm or less. The first width W1 is preferably 0.5 μm or more and 1.5 μm or less. The first depth D1 may be 1 μm or more and 10 μm or less. The first depth D1 is preferably 2 μm or more and 6 μm or less. The bottom wall of each trench structure 35 is preferably spaced from the bottom portion of the first semiconductor region 31 by 1 μm or more and 5 μm or less.

The plurality of trench structures 35 are arranged with a trench interval IT in the first direction X. The trench interval IT may be 0.25 times or more and 1.5 times or less the first width W1. The trench interval IT is preferably equal to or smaller than the first width W1. The trench interval IT may be 0.5 μm or more and 2 μm or less.

Hereinafter, the configuration of one trench structure 35 will be described. The trench structure 35 has a multi-electrode structure including a trench 36, a first insulating film 37, a second insulating film 38, a first electrode 39, a second electrode 40, and a third insulating film 41. That is, the trench structure 35 includes an electrode (gate electrode) embedded in the trench 36 with an insulator (gate insulator) interposed therebetween. The insulator includes a first insulating film 37, a second insulating film 38, and a third insulating film 41. The electrode includes a first electrode 39 and a second electrode 40.

The trench 36 is dug down from the first principal surface 3 toward the second principal surface 4 to define the wall surface of the trench structure 35. The first insulating film 37 covers the upper wall surface of the trench 36 in a film shape. Specifically, the first insulating film 37 covers the upper wall surface located in the region on the opening side of the trench 36 with respect to the bottom portion of the body region 33.

The first insulating film 37 has a portion that crosses the boundary between the first semiconductor region 31 and the body region 33 and covers the first semiconductor region 31. The first insulating film 37 may include a silicon oxide film. The first insulating film 37 preferably includes a silicon oxide film made of an oxide of the substrate 2. The first insulating film 37 is formed as a gate insulating film.

The second insulating film 38 covers the lower wall surface of the trench 36 in a film shape. Specifically, the second insulating film 38 covers the lower wall surface located in the region on the bottom wall side of the trench 36 with respect to the bottom portion of the body region 33. The second insulating film 38 covers the first semiconductor region 31. The second insulating film 38 may include a silicon oxide film. The second insulating film 38 preferably includes a silicon oxide film made of an oxide of the substrate 2. The second insulating film 38 is preferably thicker than the first insulating film 37.

The first electrode 39 is embedded on the upper side (opening side) in the trench 36 with the first insulating film 37 interposed therebetween. The first electrode 39 is embedded in a band shape extending in the second direction Y in a plan view. The first electrode 39 faces the body region 33 and the first semiconductor region 31 with the first insulating film 37 interposed therebetween. The first electrode 39 may contain conductive polysilicon. The first electrode 39 is formed as a gate electrode. A gate signal is input to the first electrode 39.

The second electrode 40 is embedded on the lower side (bottom wall side) in the trench 36 with the second insulating film 38 interposed therebetween. The second electrode 40 is embedded in a band shape extending in the second direction Y in a plan view. The second electrode 40 may have a thickness (length) exceeding the thickness (length) of the first electrode 39 in the depth direction of the trench 36.

The second electrode 40 faces the first semiconductor region 31 with the second insulating film 38 interposed therebetween. The second electrode 40 has an upper end portion protruding from the second insulating film 38 toward the first principal surface 3 side. The upper end portion of the second electrode 40 engages with the bottom portion of the second electrode 40 and faces the first insulating film 37 across the bottom portion of the second electrode 40 in the lateral direction along the first principal surface 3.

The second electrode 40 may contain conductive polysilicon. In this embodiment, the second electrode 40 is formed as a gate electrode, and is fixed at the same potential as the first electrode 39. That is, the same gate signal is applied to the second electrode 40 simultaneously with the first electrode 39. Thereby, the voltage drop between the first electrode 39 and the second electrode 40 is suppressed, and as a result, the electric field concentration between the first electrode 39 and the second electrode 40 is suppressed. Also, as a result of an increase in the carrier density in the vicinity of the trench 36, the on-resistance of the substrate 2 (particularly, the first semiconductor region 31) decreases.

The third insulating film 41 is interposed between the first electrode 39 and the second electrode 40, and electrically insulates the first electrode 39 and the second electrode 40. The third insulating film 41 covers a portion of the second electrode 40 exposed from the second insulating film 38, and is continuous with the first insulating film 37 and the second insulating film 38. The third insulating film 41 may include a silicon oxide film. The third insulating film 41 preferably includes a silicon oxide film made of an oxide of the second electrode 40. The third insulating film 41 is preferably thinner than the second insulating film 38.

The semiconductor chip 1 includes a plurality of trench connection structures 45 formed on the first principal surface 3 in the output region 6. The plurality of trench connection structures 45 are formed in a region on one end portion side of the plurality of trench structures 35 and a region on the other end portion side of the plurality of trench structures 35, respectively. FIG. 4 illustrates a region on one end portion side of the plurality of trench structures 35.

Each of the plurality of trench connection structures 45 is formed in a band shape extending in the second direction Y so as to connect one end portions of at least two (two in this embodiment) trench structures 35 adjacent in the first direction X. Each of the plurality of trench connection structures 45 is formed in a band shape extending in the second direction Y so as to connect the other end portions of at least two (in this embodiment, two) trench structures 35 adjacent in the first direction X.

The plurality of trench connection structures 45 constitute one unit trench structure in an annular or ladder shape together with the plurality of trench structures 35 in a plan view. The plurality of trench connection structures 45 are formed at intervals from the bottom portion of the first semiconductor region 31 toward the first principal surface 3 side, and face the second semiconductor region 32 with a part of the first semiconductor region 31 interposed therebetween.

The trench connection structure 45 on the other side has the same structure as the trench connection structure 45 on one side except that it is connected to the other end portions of the plurality of trench structures 35. Hereinafter, the configuration of one trench connection structure 45 on one side will be described, and the description of the trench connection structure 45 on the other side will be omitted.

The trench connection structure 45 includes a first trench portion 45a extending in the first direction X and a plurality of (two in this embodiment) second trench portions 45b extending in the second direction Y. The first trench portion 45a faces the plurality of one end portions in a plan view. The plurality of second trench portions 45b extend from the first trench portion 45a toward one end portions of the plurality of trench structures 35, and are connected to the plurality of one end portions.

The trench connection structure 45 has a second width W2 and a second depth D2. The second width W2 is a width in a direction orthogonal to the direction in which the trench connection structure 45 extends. The second width W2 is preferably substantially equal to the first width W1 of the trench structure 35. The second depth D2 is preferably substantially equal to the first depth D1 of the trench structure 35. The bottom wall of the trench connection structure 45 is preferably spaced from the bottom portion of the first semiconductor region 31 by 1 μm or more and 5 μm or less.

The trench connection structure 45 has a single electrode structure including a connection trench 46, a connection insulating film 47, and a connection electrode 48. The connection trench 46 is dug down from the first principal surface 3 toward the second principal surface 4, and defines the wall surface of the trench connection structure 45. The side wall and bottom wall of the connection trench 46 are connected to the side wall and bottom wall of the trench 36 of the trench structure 35.

The connection insulating film 47 covers the wall surface of the connection trench 46 in a film shape. The connection insulating film 47 is connected to the first insulating film 37 and the second insulating film 38 at the communication portion between the trench 36 and the connection trench 46. The connection insulating film 47 may include a silicon oxide film. The connection insulating film 47 preferably includes a silicon oxide film made of an oxide of the substrate 2. The connection insulating film 47 is preferably thicker than the first insulating film 37. The thickness of the connection insulating film 47 may be substantially equal to the thickness of the second insulating film 38.

The connection electrode 48 is embedded in the connection trench 46 with the connection insulating film 47 interposed therebetween. The connection electrode 48 may contain conductive polysilicon. The connection electrode 48 extends in the first direction X in the first trench portion 45a and extends in the second direction Y in the second trench portion 45b. The connection electrode 48 is connected to the second electrode 40 at a communication portion between the trench 36 and the connection trench 46, and faces the first electrode 39 with the third insulating film 41 interposed therebetween. The same gate signal is applied to the connection electrode 48 simultaneously with the first electrode 39 and the second electrode 40.

The semiconductor chip 1 includes a plurality of n-type source regions 51 each formed in regions along the plurality of trench structures 35 in a surface layer portion of the body region 33 of the output region 6 and the current detecting region 7. The n-type impurity concentration of the plurality of source regions 51 is higher than that of the first semiconductor region 31. The plurality of source regions 51 are arranged on both sides of each trench structure 35, and are arranged at intervals along each trench structure 35. The plurality of source regions 51 are formed at intervals from the bottom portion of the body region 33 toward the first principal surface 3 side, and face the first electrode 39 with the corresponding first insulating film 37 interposed therebetween. The plurality of source regions 51 along one trench structure 35 are preferably arranged to be shifted in the second direction Y with respect to the plurality of source regions 51 along the other trench structure 35. That is, it is preferable that the plurality of source regions 51 along one trench structure 35 face a region between the plurality of source regions 51 along the other trench structure 35 in the first direction X.

The semiconductor chip 1 includes a plurality of p-type contact regions 52 each formed in regions along the plurality of trench structures 35 in a surface layer portion of the body region 33 of the output region 6 and the current detecting region 7. The p-type impurity concentration of the plurality of contact regions 52 is higher than that of the body region 33.

The plurality of contact regions 52 are arranged on both sides of each trench structure 35, and are arranged at intervals along each trench structure 35. The plurality of contact regions 52 are formed at intervals from the bottom portion of the body region 33 toward the first principal surface 3 side, and face the first electrode 39 with the corresponding first insulating film 37 interposed therebetween.

The plurality of contact regions 52 are alternately arranged with the plurality of source regions 51 on both sides of each trench structure 35. The plurality of contact regions 52 along one trench structure 35 are preferably arranged to be shifted in the second direction Y with respect to the plurality of contact regions 52 along the other trench structure 35. That is, it is preferable that the plurality of contact regions 52 along one trench structure 35 face a region (that is, the source region 51) between the plurality of contact regions 52 along the other trench structure 35 in the first direction X.

The semiconductor chip 1 includes n gate wirings 53 disposed in the interlayer insulating film 24 in a mutually electrically independent state. The n gate wirings 53 include n gate wirings 53 for the main transistor 11 and n gate wirings 53 for the monitor transistor 13. The n gate wirings 53 are selectively electrically connected to the corresponding at least one trench structure 35 via the plurality of first via electrodes 54 in the output region 6 and the current detecting region 7, and are electrically connected to the control circuit 17 (gate driving circuit 18) in the control region 8. The plurality of first via electrodes 54 may contain tungsten.

Specifically, the n gate wirings 53 for the main transistor 11 are electrically connected to at least one (in this embodiment, a plurality of) trench structures 35 and at least one (in this embodiment, a plurality of) trench connection structures 45 to be systematized (grouped) as the system transistor 12 via the plurality of first via electrodes 54 in the output region 6, respectively.

Here, an example in which the n gate wirings 53 for the main transistor 11 include the first gate wirings 53A for the first-system transistor 12A and the second gate wirings 53B for the second-system transistor 12B will be described. The first gate wiring 53A is electrically connected to a plurality of unit trench structures (a plurality of trench structures 35 and a plurality of trench connection structures 45) to be systematized (grouped) as the first-system transistor 12A via a plurality of first via electrodes 54 in the output region 6.

The second gate wiring 53B is disposed in the interlayer insulating film 24 in a state of being electrically independent from the first gate wiring 53A. The second gate wiring 53B is electrically connected to a plurality of unit trench structures (a plurality of trench structures 35 and a plurality of trench connection structures 45) to be systematized (grouped) as the second-system transistor 12B via the plurality of first via electrodes 54 in the output region 6. In this embodiment, the plurality of unit trench structures for the second-system transistor 12B and the plurality of unit trench structures for the first-system transistor 12A are alternately systematized.

On the other hand, the n gate wirings 53 for the monitor transistor 13 are electrically connected to at least one (in this embodiment, a plurality of) trench structures 35 and at least one (in this embodiment, a plurality of) trench connection structures 45 to be systematized (grouped) as the system monitor transistor 14 via the plurality of first via electrodes 54 in the current detecting region 7. The number of trench structures 35 (the number of trench connection structures 45) constituting the system monitor transistor 14 is smaller than the number of trench structures 35 (the number of trench connection structures 45) constituting the system transistor 12.

Here, an example in which the n gate wirings 53 for the monitor transistor 13 include the first gate wirings 53A for the first-system monitor transistor 14A and the second gate wirings 53B for the second-system monitor transistor 14B will be described. The first gate wiring 53A is electrically connected to at least one trench structure 35 and at least one trench connection structure 45 to be systematized as the first-system monitor transistor 14A via the plurality of first via electrodes 54 in the current detecting region 7.

The second gate wiring 53B is disposed in the interlayer insulating film 24 in a state of being electrically independent from the first gate wiring 53A. The second gate wiring 53B is electrically connected to at least one trench structure 35 and at least one trench connection structure 45 to be systematized as the second-system monitor transistor 14B via the plurality of first via electrodes 54 in the current detecting region 7. The trench structure 35 for the second-system monitor transistor 14B may be adjacent to the trench structure 35 for the first-system monitor transistor 14A.

The first gate wiring 53A for the monitor transistor 13 may be formed integrally with the first gate wiring 53A for the main transistor 11. The second gate wiring 53B for the monitor transistor 13 may be formed integrally with the second gate wiring 53B for the main transistor 11.

The semiconductor chip 1 includes a plurality of source wirings 55 disposed in the interlayer insulating film 24. The plurality of source wirings 55 include a first source wiring 55A for the main transistor 11 and a second source wiring 55B for the monitor transistor 13. The first source wiring 55A covers the output region 6 in the interlayer insulating film 24, and is electrically connected to the plurality of source regions 51 and the plurality of contact regions 52 via the plurality of second via electrodes 56. The plurality of second via electrodes 56 may contain tungsten.

The second source wiring 55B is selectively routed in a region between the current detecting region 7 and the control region 8 in the interlayer insulating film 24. The second source wiring 55B is electrically connected to the plurality of source regions 51 and the plurality of contact regions 52 via the plurality of second via electrodes 56 in the current detecting region 7, and is electrically connected to the control circuit 17 (overcurrent protection circuit 20) in the control region 8.

The semiconductor chip 1 includes the above-described source terminal 26 disposed on the interlayer insulating film 24. In this embodiment, the source terminal 26 overlaps the plurality of source wirings 55 (the first source wiring 55A and the second source wiring 55B) in a plan view, and covers all the trench structures 35 and all the trench connection structures 45.

The source terminal 26 is electrically connected to the first source wiring 55A via the plurality of third via electrodes 57 disposed in the interlayer insulating film 24. The plurality of third via electrodes 57 are arranged in a region between the plurality of second via electrodes 56 in a plan view and a cross-sectional view. That is, in this embodiment, the plurality of third via electrodes 57 do not face the second via electrodes 56 with the first source wiring 55A interposed therebetween. As a matter of course, the plurality of third via electrodes 57 may face the second via electrodes 56 with the first source wiring 55A interposed therebetween.

The source terminal 26 preferably has a thickness larger than that of the source wiring 55. The thickness of the source terminal 26 is preferably larger than the first depth D1 of the plurality of trench structures 35 (the second depth D2 of the trench connection structure 45). The thickness of the source terminal 26 is preferably larger than the thickness of the interlayer insulating film 24. The thickness of the source terminal 26 may be 1 μm or more and 25 μm or less.

The thickness of the source terminal 26 may be 1 μm or more and 5 μm or less, 5 μm or more and 10 μm or less, 10 μm or more and 15 μm or less, 15 μm or more and 20 μm or less, or 20 μm or more and 25 μm or less. In a case where the source terminal 26 contains an Al-based metal as a main component, the thickness of the source terminal 26 may be 1 μm or more and 10 μm or less. When the source terminal 26 contains a Cu-based metal as a main component, the thickness of the source terminal 26 may be 10 μm or more and 25 μm or less.

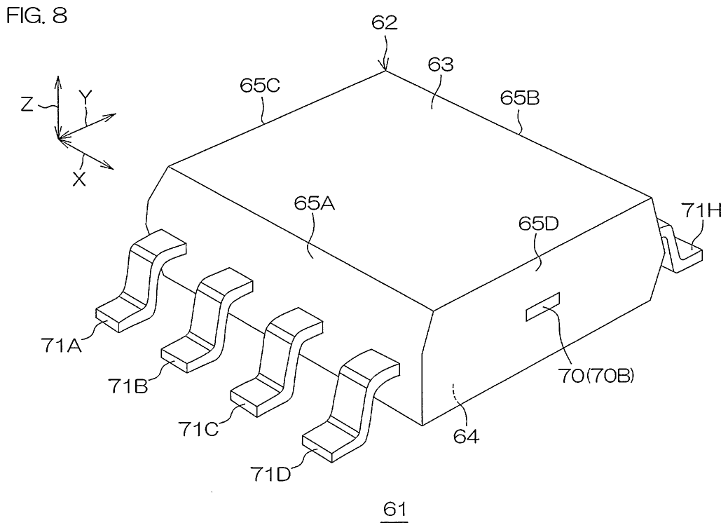

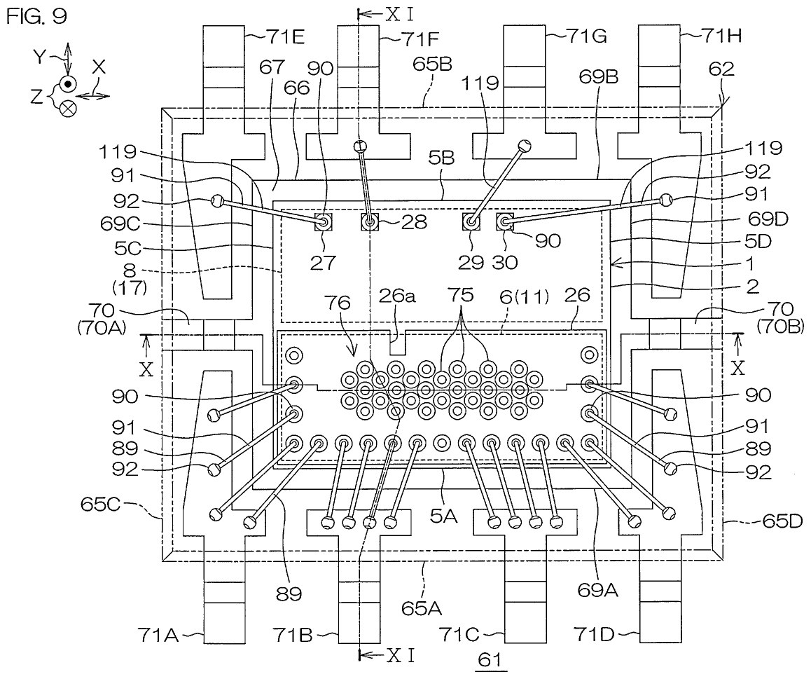

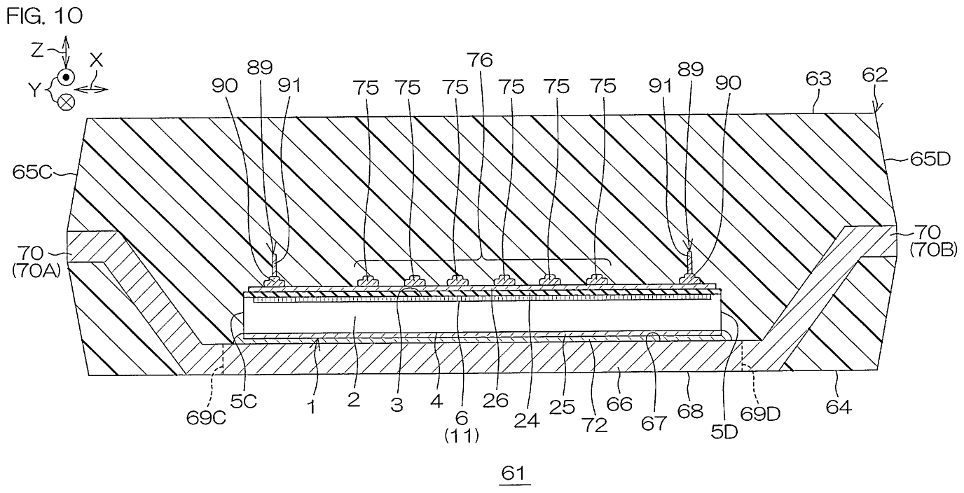

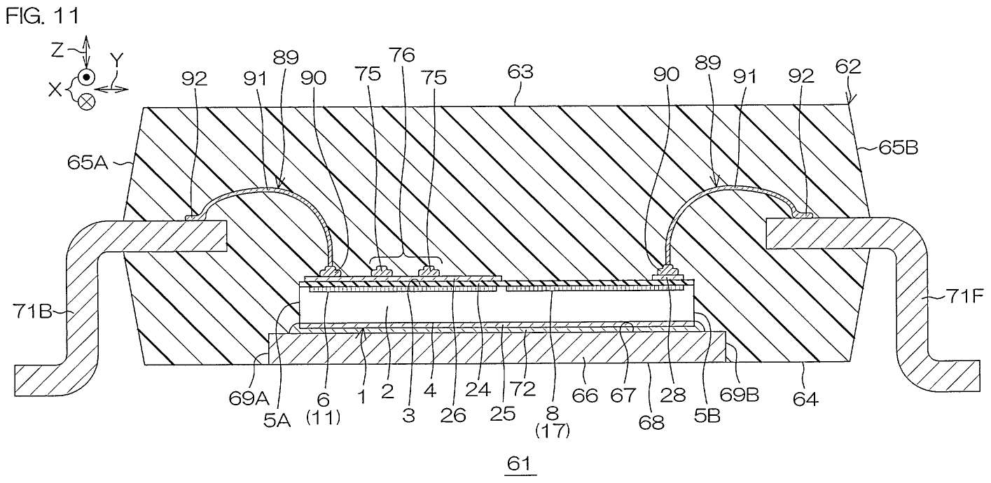

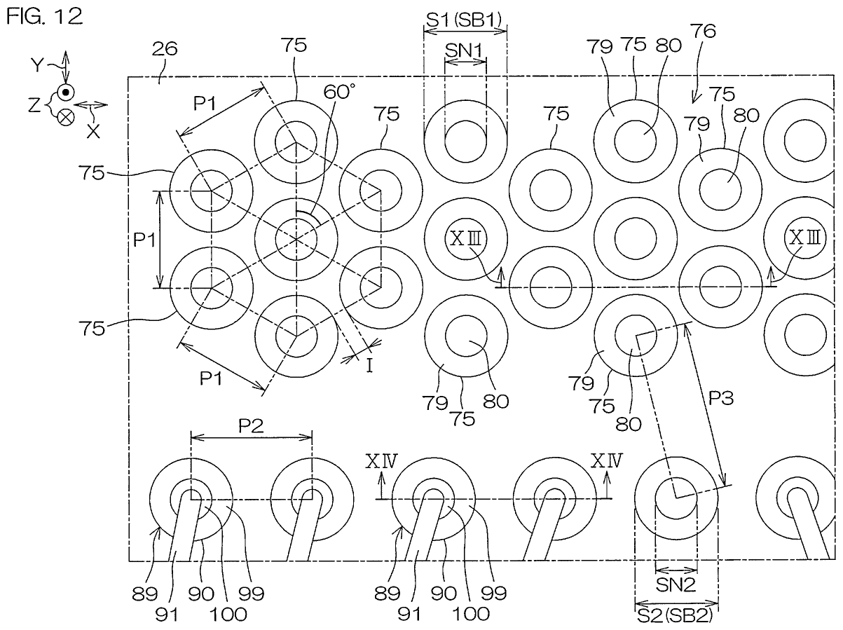

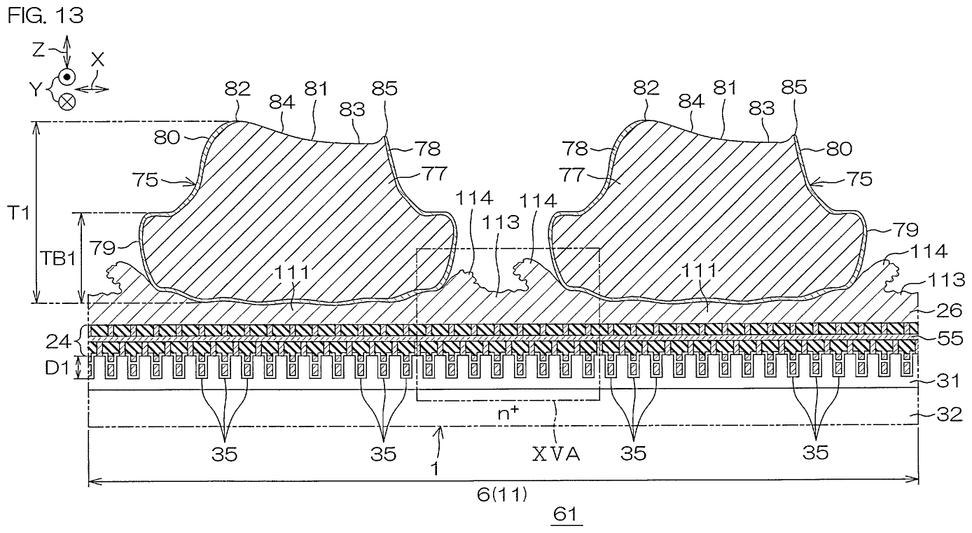

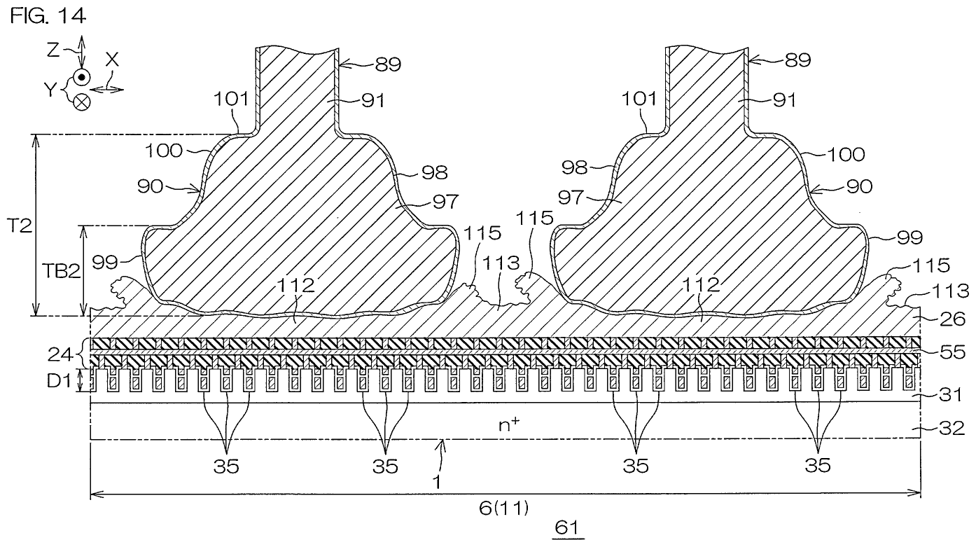

FIG. 8 is a perspective view illustrating a semiconductor device 61 on which the semiconductor chip 1 illustrated in FIG. 1 is mounted. FIG. 9 is a plan view illustrating an internal structure of the semiconductor device 61 illustrated in FIG. 8. FIG. 10 is a cross-sectional view taken along line X-X illustrated in FIG. 9. FIG. 11 is a cross-sectional view taken along line XI-XI illustrated in FIG. 9. FIG. 12 is an enlarged plan view illustrating a part of FIG. 9. FIG. 13 is a cross-sectional view taken along line XIII-XIII illustrated in FIG. 12. FIG. 14 is a cross-sectional view taken along line XIV-XIV illustrated in FIG. 12.

Referring to FIGS. 8 to 14, the semiconductor device 61 may be referred to as a “semiconductor package” or a “semiconductor module.” The package type of the semiconductor device 61 takes various forms according to a use environment, a mounting object, a form of the semiconductor chip 1, and the like. Here, a form in which the semiconductor device 61 includes an 8-terminal type small outline package (SOP) is exemplified.

The semiconductor device 61 includes a rectangular parallelepiped package body 62. The package body 62 includes a matrix resin and a plurality of fillers. The matrix resin may be a thermosetting resin (for example, an epoxy resin). The plurality of fillers may be insulating spheres (e.g., silica particles).

The package body 62 includes a first surface 63 on one side, a second surface 64 on the other side, and first to fourth side walls 65A to 65D connecting the first surface 63 and the second surface 64. The first surface 63 is a mounting surface, and the second surface 64 is a non-mounting surface. The first surface 63 and the second surface 64 are formed in a quadrangular shape (in this embodiment, a rectangular shape extending in the first direction X) in a plan view.

The first side wall 65A and the second side wall 65B extend in the first direction X along the first principal surface 3 and face each other in the second direction Y. The first side wall 65A and the second side wall 65B form a long side of the package body 62. The third side wall 65C and the fourth side wall 65D extend in the second direction Y and face each other in the first direction X. The third side wall 65C and the fourth side wall 65D form a short side of the package body 62.

The semiconductor device 61 includes a rectangular parallelepiped metal plate 66 disposed in the package body 62. The metal plate 66 may be referred to as a “die pad” made of metal. The metal plate 66 has a first plate surface 67 on one side, a second plate surface 68 on the other side, and first to fourth plate side walls 69A to 69D connecting the first plate surface 67 and the second plate surface 68.

The first plate surface 67 and the second plate surface 68 are formed in a quadrangular shape (in this embodiment, a rectangular shape extending in the first direction X) in a plan view. The second plate surface 68 is exposed from the second surface 64 of the package body 62. As a matter of course, the metal plate 66 may be disposed in the package body 62 such that the second plate surface 68 is not exposed from the second surface 64.

The first plate side wall 69A and the second plate side wall 69B extend in the first direction X along the first principal surface 3 and face each other in the second direction Y. The first plate side wall 69A and the second plate side wall 69B form long sides of the metal plate 66. The third plate side wall 69C and the fourth plate side wall 69D extend in the second direction Y and face each other in the first direction X. The third plate side wall 69C and the fourth plate side wall 69D form short sides of the metal plate 66.

The semiconductor device 61 includes at least one (in this embodiment, a plurality of) extension portions 70 drawn out from the metal plate 66 toward at least one of the first to fourth side walls 65A to 65D in the package body 62. The plurality of extension portions 70 include a first extension portion 70A and a second extension portion 70B.

The first extension portion 70A is drawn out in a band shape from the third plate side wall 69C toward the third side wall 65C. In this embodiment, the first extension portion 70A has a bent portion bent toward the first surface 63, and is exposed from a middle portion of the thickness range of the package body 62 in the third side wall 65C. The second extension portion 70B is drawn out in a band shape from the fourth plate side wall 69D toward the fourth side wall 65D. In this embodiment, the second extension portion 70B has a bent portion bent toward the first surface 63, and is exposed from the middle portion of the thickness range of the package body 62 in the fourth side wall 65D.

The semiconductor device 61 includes first to eighth lead terminals 71A to 71H made of metal and disposed in the package body 62 with a space from the metal plate 66 so as to be drawn out from the inside to the outside of the package body 62. The first to fourth lead terminals 71A to 71D are arranged at intervals in the first direction X on the first side wall 65A side, and are each formed in a band shape extending in the second direction Y. The fifth to eighth lead terminals 71E to 71H are arranged at intervals in the first direction X on the second side wall 65B side, and are each formed in a band shape extending in the second direction Y.

The first to eighth lead terminals 71A to 71H each have an inner end portion, a band portion, and an outer end portion. The inner end portion is disposed in the middle portion of the thickness range of the package body 62 so as to be positioned on the first surface 63 side with respect to the height position of the metal plate 66. The planar shape of the inner end portion is arbitrary. The band portion is drawn out from the inner end portion to the outside of the package body 62, and is bent toward the second surface 64 side outside the package body 62. The band portion extends to a height position crossing the second surface 64 of the package body 62. The outer end portion extends substantially parallel to the second surface 64 at a height position below the second surface 64 of the package body 62.

The semiconductor device 61 includes the semiconductor chip 1 disposed on the metal plate 66 (first plate surface 67) in the package body 62. The semiconductor chip 1 is disposed on the metal plate 66 in a posture in which the drain terminal 25 faces the metal plate 66 (first plate surface 67).

The semiconductor device 61 includes a conductive bonding material 72 interposed between the semiconductor chip 1 and the metal plate 66 in the package body 62. Specifically, the conductive bonding material 72 is interposed between the drain terminal 25 and the metal plate 66, and electrically and mechanically connects the drain terminal 25 and the metal plate 66. The conductive bonding material 72 may contain solder or a metal paste. The solder may be lead-free solder. The metal paste may contain at least one of Au, Ag, and Cu. The Ag paste may be composed of an Ag sintering paste.

The semiconductor device 61 includes a plurality of pseudo bumps 75 disposed on the source terminal 26 in a state of being released from the wire in the package body 62. Each of the plurality of pseudo bumps 75 is made of a metal lump formed using a wire bonding step with respect to the source terminal 26. The wire bonding step is performed using a capillary (wire supply device) of the bonding device.

The plurality of pseudo bumps 75 are arranged on the source terminal 26 more densely than the authentic bumps 90 to be described later. The phrase “denser than the authentic bump 90” means that the area occupied by the plurality of pseudo bumps 75 with respect to the source terminal 26 is larger than that of other structures (authentic bumps 90 to be described later) connected to the source terminal 26. The plurality of pseudo bumps 75 are arranged on the source terminal 26 with a first occupied area per unit planar area.

Referring to FIG. 12, each of the plurality of pseudo bumps 75 has a first size S1 in a plan view. The first size S1 is defined by the length of the widest portion of the pseudo bump 75 in a plan view. The first size S1 may be 50 μm or more and 250 μm or less.

The first size S1 may be 50 μm or more and 75 μm or less, 75 μm or more and 100 μm or less, 100 μm or more and 125 μm or less, 125 μm or more and 150 μm or less, 150 μm or more and 175 μm or less, 175 μm or more and 200 μm or less, 200 μm or more and 225 μm or less, or 225 μm or more and 250 μm or less. The first size S1 is preferably 75 μm or more and 200 μm or less. The first size S1 is particularly preferably 100 μm or more and 180 μm or less.

The plurality of pseudo bumps 75 are arranged on the source terminal 26 at a first pitch P1 in a plan view. The first pitch P1 is defined by a distance between the center portions of the plurality of pseudo bumps 75. The plurality of pseudo bumps 75 may be arranged so as to be in contact with each other at the first pitch P1, or may be arranged at intervals from each other at the first pitch P1. The plurality of pseudo bumps 75 are preferably arranged at intervals from each other.

The first pitch P1 is preferably 1 time or more and 2.5 times or less the first size S1. The ratio P1/S1 of the first pitch P1 to the first size S1 may be 1 or more and 1.25 or less, 1.25 or more and 1.5 or less, 1.5 or more and 1.75 or less, 1.75 or more and 2 or less, 2 or more and 2.25 or less, or 2.25 or more and 2.5 or less. The ratio P1/S1 is preferably larger than 1. The ratio P1/S1 is particularly preferably 1.25 or more and 1.75 or less.

The first pitch P1 may be 50 μm or more and 250 μm or less. The first pitch P1 may be 50 μm or more and 75 μm or less, 75 μm or more and 100 μm or less, 100 μm or more and 125 μm or less, 125 μm or more and 150 μm or less, 150 μm or more and 175 μm or less, 175 μm or more and 200 μm or less, 200 μm or more and 225 μm or less, or 225 μm or more and 250 μm or less. The first pitch P1 is preferably 75 μm or more and 200 μm or less. The first pitch P1 is particularly preferably 100 μm or more and 180 μm or less.

The interval I between the plurality of pseudo bumps 75 may be 0 μm or more and 100 μm or less. The interval I may be 0 μm or more and 10 μm or less, 10 μm or more and 20 μm or less, 20 μm or more and 30 μm or less, 30 μm or more and 40 μm or less, 40 μm or more and 50 μm or less, 50 μm or more and 60 μm or less, 60 μm or more and 70 μm or less, 70 μm or more and 80 μm or less, 80 μm or more and 90 μm or less, or 90 μm or more and 100 μm or less. The interval I is preferably 10 μm or more. The interval I is particularly preferably 30 μm or more and 60 μm or less.

Referring to FIG. 13, each of the plurality of pseudo bumps 75 has a first thickness T1. The first thickness T1 is defined by the thickness of the thickest portion of the pseudo bump 75 in a cross-sectional view. The first thickness T1 is preferably larger than the first depth D1 of the plurality of trench structures 35. The first thickness T1 is preferably larger than the thickness of the source terminal 26. The first thickness T1 is preferably larger than the thickness of the first semiconductor region 31. The first thickness T1 may be larger than the thickness of the substrate 2. As a matter of course, the first thickness T1 may be smaller than the thickness of the substrate 2.

The first thickness T1 may be 10 μm or more and 150 μm or less. The first thickness T1 may be 10 μm or more and 25 μm or less, 25 μm or more and 50 μm or less, 50 μm or more and 75 μm or less, 75 μm or more and 100 μm or less, 100 μm or more and 125 μm or less, or 125 μm or more and 150 μm or less. The first thickness T1 is preferably 25 μm or more and 100 μm. The first thickness T1 is particularly preferably 50 μm or more.

It is preferable that at least three pseudo bumps 75 are arranged on the source terminal 26 as a pseudo bump group 76. In this case, it is preferable that at least three pseudo bumps 75 are arranged in a layout located at vertexes of an isosceles triangle in a plan view. The isosceles triangle is particularly preferably an equilateral triangle. That is, a plurality of pseudo bumps 75 are arranged in a layout located at vertexes of a triangle in a plan view, and a fourth bump is not arranged in a space surrounded by three pseudo bumps 75. This embodiment may be defined as “the plurality of pseudo bumps 75 are densely arranged.”

It is preferable that at least seven pseudo bumps 75 are arranged on the source terminal 26 as a pseudo bump group 76. In this case, it is preferable that six pseudo bumps 75 are arranged around one pseudo bump 75 in a plan view. The seven pseudo bumps 75 may include one center bump 73 and six peripheral bumps 74 arranged concentrically around the center portion of the center bump 73 in a plan view.

It is preferable that the six peripheral bumps 74 are arranged in a layout located at vertexes of the hexagon in a plan view, and one center bump 73 is disposed in a layout located at the center of the hexagon in a plan view. That is, it is preferable that the plurality of pseudo bumps 75 are bonded to the source terminal 26 in a layout that is a hexagonal close-packed array (that is, a honeycomb array) in a plan view. In this case, the hexagon is most preferably a regular hexagon.

In FIG. 9, the pseudo bump group 76 including twenty eight pseudo bumps 75 arranged in a hexagonal close-packed array is bonded to the source terminal 26. Although the number of pseudo bumps 75 bonded to the source terminal 26 is arbitrary, it is preferable that the pseudo bump group 76 including at least three pseudo bumps 75 and/or pseudo bump group 76 including at least seven pseudo bumps 75 are bonded to the source terminal 26. As a matter of course, the plurality of pseudo bump groups 76 may be bonded to the source terminal 26 at a distance larger than the first pitch P1 (interval I).

Bonding places of the plurality of pseudo bumps 75 (pseudo bump group 76) to the source terminal 26 may be set based on the temperature distribution of the semiconductor chip 1. For example, a high-temperature region and a low-temperature region of the output region 6 may be analyzed using thermography, a simulation tool, or the like, and a plurality of pseudo bumps 75 (pseudo bump group 76) may be bonded to a portion of the source terminal 26 covering the high-temperature region of the output region 6.

For example, the inner portion (for example, the center portion) of the output region 6 is likely to have a higher temperature than the peripheral edge portion of the output region 6. Therefore, the plurality of pseudo bumps 75 (pseudo bump group 76) may be bonded to the source terminal 26 in a layout that is dense at the inner portion (for example, the center portion) of the source terminal 26 and sparse at the peripheral edge portion of the source terminal 26. The form in which the plurality of pseudo bumps 75 are “sparse” includes a form in which the pseudo bump 75 does not exist. In this embodiment, one pseudo bump 75 is disposed in each of portions along three sides of the peripheral edge portion of the source terminal 26.

The temperature of the control region 8 is lower than the temperature of the output region 6. In this embodiment, the source terminal 26 covers the output region 6 so as to expose the control region 8, and the plurality of pseudo bumps 75 (pseudo bump group 76) are arranged in a region overlapping the output region 6 in a plan view. That is, the plurality of pseudo bumps 75 (pseudo bump group 76) are arranged at positions overlapping the main transistor 11 in a plan view, and are not arranged in the region overlapping the control region 8 in a plan view.

A part of the plurality of pseudo bumps 75 (pseudo bump group 76) may face the monitor transistor 13 in a plan view. That is, the plurality of pseudo bumps 75 (pseudo bump group 76) may face the plurality of trench structures 35 for the main transistor 11 and the plurality of trench structures 35 for the monitor transistor 13. As a matter of course, the plurality of pseudo bumps 75 (pseudo bump group 76) may be disposed on the source terminal 26 so as not to face the plurality of trench structures 35 for the monitor transistor 13.

Each of the pseudo bumps 75 may face 10 or more and 200 or less trench structures 35. The number of facing trench structures 35 according to each pseudo bump 75 may be 10 or more and 25 or less, 25 or more and 50 or less, 50 or more and 75 or less, 75 or more and 100 or less, 100 or more and 125 or less, 125 or more and 150 or less, 150 or more and 175 or less, or 175 or more and 200 or less. The number of facing trench structures 35 according to each pseudo bump 75 is preferably 25 or more and 100 or less.

Hereinafter, a specific shape of one pseudo bump 75 will be described with reference to FIGS. 12 and 13. In this embodiment, the pseudo bump 75 includes a first bump body 77 and a first bump metal film 78. The first bump body 77 contains a first metal. The first metal is made of a material different from the source terminal 26, and is preferably made of a metal harder than the source terminal 26. The first metal includes, for example, at least one of a Cu-based metal, an Al-based metal, an Au-based metal, and an Ag-based metal.

The Cu-based metal may contain pure Cu or a Cu alloy. The Al-based metal may contain pure Al or an Al alloy. The Au-based metal may contain pure Au or an Au alloy. The Ag-based metal may contain pure Ag or an Ag alloy. In this embodiment, the first bump body 77 contains pure Cu. In this case, the source terminal 26 is preferably an Al-based metal layer.

The first bump body 77 includes a first body portion 79 and a first neck portion 80. The first body portion 79 includes a wide portion connected to the source terminal 26. The first body portion 79 is formed in a substantially columnar shape having a side wall curved outward in a cross-sectional view. The first body portion 79 has a first body size SB1 that forms a first size S1 of the pseudo bump 75 in a plan view.

The first body portion 79 may have a first body thickness TB1 that is 0.1 times or more and 0.9 times or less the first thickness T1 of the pseudo bump 75. The first body thickness TB1 is preferably larger than the thickness of the first semiconductor region 31. The first body thickness TB1 may be larger than the thickness of the substrate 2. As a matter of course, the first body thickness TB1 may be smaller than the thickness of the substrate 2.

The thickness ratio T1/TB1 of the first body thickness TB1 to the first thickness T1 may be 0.1 or more and 0.2 or less, 0.2 or more and 0.3 or less, 0.3 or more and 0.4 or less, 0.4 or more and 0.5 or less, 0.5 or more and 0.6 or less, 0.6 or more and 0.7 or less, 0.7 or more and 0.8 or less, or 0.8 or more and 0.9 or less. The thickness ratio T1/TB1 is preferably 0.4 or more and 0.7 or less. The thickness ratio T1/TB1 is particularly preferably 0.5 or more.

The first neck portion 80 is formed as a portion protruding from the first body portion 79 toward the side opposite to the source terminal 26 to be narrower than the first body portion 79. The first neck portion 80 is formed in a substantially columnar shape in a cross-sectional view. In this embodiment, the first neck portion 80 has a first upper end portion 81 inclined obliquely downward. Specifically, the first upper end portion 81 may have an upper end top portion 82, an upper end base portion 83, and an inclined portion 84 in a cross-sectional view.

The upper end top portion 82 is formed on one side of the peripheral edge portion of the first upper end portion 81 in a cross-sectional view. The upper end base portion 83 is formed on the other side of the peripheral edge portion of the first upper end portion 81 in a cross-sectional view, and is located on the first body portion 79 side with respect to the height position of the upper end top portion 82. The inclined portion 84 is inclined obliquely downward from the upper end top portion 82 toward the upper end base portion 83 in a cross-sectional view. The first upper end portion 81 may have an upper end protrusion portion 85 protruding toward the side opposite to the first body portion 79 at the upper end base portion 83. The distal end portion of the upper end protrusion portion 85 may be formed at a height position on the first body portion 79 side with respect to the height position of the distal end portion of the upper end top portion 82.

The first neck portion 80 has a first neck size SN1 smaller than the first body size SB1 in a plan view. The first neck size SN1 may be 0.1 times or more and 0.9 times or less the first body size SB1 (first size S1).

The size ratio SN1/SB1 of the first neck size SN1 to the first body size SB1 may be 0.1 or more and 0.2 or less, 0.2 or more and 0.3 or less, 0.3 or more and 0.4 or less, 0.4 or more and 0.5 or less, 0.5 or more and 0.6 or less, 0.6 or more and 0.7 or less, 0.7 or more and 0.8 or less, or 0.8 or more and 0.9 or less. The size ratio SN1/SB1 is preferably 0.5 or more and 0.7 or less. The size ratio SN1/SB1 is particularly preferably larger than 0.5.

The first bump metal film 78 includes a second metal different from the first metal of the first bump body 77 and covers at least a part of the outer surface of the first bump body 77. The first bump metal film 78 covers a region outside the upper end top portion 82 so as to expose the upper end top portion 82 of the outer surface of the first bump body 77.

FIG. 13 illustrates a form in which the first bump metal film 78 covers the entire region outside the upper end top portion 82, but the first bump metal film 78 does not necessarily have such a form. Also, the form of the first bump metal film 78 between the plurality of pseudo bumps 75 is indefinite, and is not fixed to a certain form.

For example, the first bump metal film 78 may cover at least a part of the outer surface of the first bump body 77 so as to partially expose the first bump body 77 (first metal) in the region outside the upper end top portion 82, and a part of the first bump metal film 78 may be located inside the first bump body 77.

For example, a part of the first bump metal film 78 may be dissolved in the first bump body 77. For example, the covering area of the first bump metal film 78 with respect to the first bump body 77 may be smaller than the exposed area of the first bump body 77 with respect to the first bump metal film 78. As a matter of course, the covering area of the first bump metal film 78 with respect to the first bump body 77 may be equal to or larger than the exposed area of the first bump body 77 with respect to the first bump metal film 78.

The first bump metal film 78 is preferably made of a plating film. The first bump metal film 78 preferably includes at least one of an Ni plating film, a Pd plating film, and an Au plating film. For example, the first bump metal film 78 may have a laminated structure including an Ni plating film, a Pd plating film, and an Au plating film laminated in this order from the first bump body 77.

For example, the first bump metal film 78 may have a laminated structure including an Ni plating film and a Pd plating film laminated in this order from the first bump body 77. For example, the first bump metal film 78 may have a single-layer structure made of an Ni plating film, a Pd plating film, or an Au plating film.

The semiconductor device 61 includes at least one (in this embodiment, a plurality of) first bonding wires 89 disposed in the package body 62. The plurality of first bonding wires 89 electrically connect the source terminal 26 to at least one connection target (in this embodiment, the first to fourth lead terminals 71A to 71D) selected from the first to eighth lead terminals 71A to 71H. The number of first bonding wires 89 may be one or more, and is not limited to a specific number.

In this embodiment, four first bonding wires 89 are connected to the source terminal 26 and the first lead terminal 71A, four first bonding wires 89 are connected to the source terminal 26 and the second lead terminal 71B, four first bonding wires 89 are connected to the source terminal 26 and the third lead terminal 71C, and four first bonding wires 89 are connected to the source terminal 26 and the fourth lead terminal 71D.

The plurality of first bonding wires 89 each include an authentic bump 90, a wire loop 91, and a wire tail 92. The authentic bump 90 is a metal lump bonded to the source terminal 26 in a state of being connected to the wire (wire loop 91). The wire loop 91 is a wire portion extending in an arch shape in a region between the authentic bump 90 and the connection target. The wire tail 92 is a wire end portion bonded to a connection target. The plurality of first bonding wires 89 are formed through a wire bonding step using a capillary (wire supply device) of a bonding device.

Hereinafter, the form of the plurality of authentic bumps 90 will be described. The plurality of authentic bumps 90 are arranged on the source terminal 26 with a space from the plurality of pseudo bumps 75 (pseudo bump group 76). In this embodiment, the plurality of authentic bumps 90 are arranged on the peripheral edge portion of the source terminal 26 at intervals along the peripheral edge of the source terminal 26. The arrangement position of the plurality of authentic bumps 90 may be any empty region between the peripheral edge of the source terminal 26 and the plurality of pseudo bumps 75 (pseudo bump group 76), and is not limited to a specific arrangement position.

The plurality of authentic bumps 90 are arranged more sparsely on the source terminal 26 than the plurality of pseudo bumps 75. The term “sparse” as used herein means that the area occupied by the plurality of authentic bumps 90 with respect to the source terminal 26 is smaller than the area occupied by the plurality of pseudo bumps 75 with respect to the source terminal 26.

Even in a case where only the single authentic bump 90 is disposed on the source terminal 26 and the occupied area of the single authentic bump 90 is smaller than the occupied area of the plurality of pseudo bumps 75, the case is included in the form in which the authentic bumps 90 are arranged “sparsely.” That is, one or more authentic bumps 90 may be arranged on the source terminal 26 with a second occupied area smaller than the first occupied area of the plurality of pseudo bumps 75 per unit planar area.

Each of the plurality of authentic bumps 90 has a second size S2 in a plan view. The second size S2 is defined by the length of the widest portion of the authentic bump 90 in a plan view. The second size S2 may be 50 μm or more and 250 μm or less.

The second size S2 may be 50 μm or more and 75 μm or less, 75 μm or more and 100 μm or less, 100 μm or more and 125 μm or less, 125 μm or more and 150 μm or less, 150 μm or more and 175 μm or less, 175 μm or more and 200 μm or less, 200 μm or more and 225 μm or less, or 225 μm or more and 250 μm or less. The second size S2 is preferably 75 μm or more and 200 μm or less. The second size S2 is particularly preferably 100 μm or more and 180 μm or less.

The second size S2 may be equal to or larger than the first size S1 of the pseudo bump 75 or may be smaller than the first size S1. The second size S2 is preferably substantially equal to the first size S1. According to this configuration, the pseudo bump 75 and the authentic bump 90 can be formed under the same manufacturing condition regarding the size.

The plurality of authentic bumps 90 are arranged on the source terminal 26 at the second pitch P2 equal to or larger than the first pitch P1 of the pseudo bump 75 in a plan view. The second pitch P2 is defined by the distance between the center portions of the two authentic bumps 90 adjacent to each other. It is preferable that the plurality of authentic bumps 90 are arranged at intervals from each other at the second pitch P2 so as not to contact each other.

The second pitch P2 takes an arbitrary value in a condition that the entire authentic bump 90 is located within a range surrounded by the peripheral edge of the source terminal 26 and the second pitch P2 is equal to or larger than the first pitch P1. As an example, the pitch ratio P2/P1 of the second pitch P2 to the first pitch P1 may be 1 or more and 20 or less. The pitch ratio P2/P1 may be 1 or more and 2 or less, 2 or more and 5 or less, 5 or more and 10 or less, 10 or more and 15 or less, or 15 or more and 20 or less. The pitch ratio P2/P1 is preferably larger than 1.

The plurality of authentic bumps 90 are arranged on the source terminal 26 at a third pitch P3 based on one adjacent pseudo bump 75. The third pitch P3 is defined by a distance between center portions of the pseudo bump 75 and the authentic bump 90 adjacent to each other. The third pitch P3 is preferably equal to or larger than the first pitch P1 of the pseudo bump 75. It is preferable that the at least one authentic bump 90 is disposed at the third pitch P3 larger than the first pitch P1. In this embodiment, all the authentic bumps 90 are arranged at the third pitch P3 larger than the first pitch P1.

The third pitch P3 takes an arbitrary value in a condition that the entire authentic bump 90 is located within a range surrounded by the peripheral edge of the source terminal 26 and the third pitch P3 is equal to or larger than the first pitch P1. As an example, the pitch ratio P3/P1 of the third pitch P3 to the first pitch P1 may be 1 or more and 20 or less. The pitch ratio P2/P1 may be 1 or more and 2 or less, 2 or more and 5 or less, 5 or more and 10 or less, 10 or more and 15 or less, or 15 or more and 20 or less.

Each of the plurality of authentic bumps 90 has a second thickness T2. The second thickness T2 is defined by the thickness of the thickest portion of the authentic bump 90 in a cross-sectional view. The second thickness T2 is preferably larger than the first depth D1 of the plurality of trench structures 35. The second thickness T2 is preferably larger than the thickness of the source terminal 26. The second thickness T2 is preferably larger than the thickness of the first semiconductor region 31. The second thickness T2 may be larger than the thickness of the substrate 2. As a matter of course, the second thickness T2 may be smaller than the thickness of the substrate 2.

The second thickness T2 may be 10 μm or more and 150 μm or less. The second thickness T2 may be 10 μm or more and 25 μm or less, 25 μm or more and 50 μm or less, 50 μm or more and 75 μm or less, 75 μm or more and 100 μm or less, 100 μm or more and 125 μm or less, or 125 μm or more and 150 μm or less. The second thickness T2 is preferably 25 μm or more and 100 μm or less. The second thickness T2 is particularly preferably 50 μm or more.

The second thickness T2 may be equal to or larger than the first thickness T1 of the pseudo bump 75, or may be smaller than the first thickness T1. The second thickness T2 is preferably substantially equal to the first thickness T1. According to this configuration, the pseudo bump 75 and the authentic bump 90 can be formed under the same manufacturing condition regarding the thickness.

The plurality of authentic bumps 90 are arranged in a region overlapping the output region 6 in a plan view. That is, the plurality of authentic bumps 90 are arranged at positions overlapping the main transistor 11 in a plan view, and are not arranged in a region overlapping the control region 8 in a plan view. A part of the plurality of authentic bumps 90 may face the monitor transistor 13 in a plan view.

That is, the plurality of authentic bumps 90 may face the plurality of trench structures 35 for the main transistor 11 and the plurality of trench structures 35 for the monitor transistor 13. As a matter of course, the plurality of authentic bumps 90 may be arranged on the source terminal 26 so as not to face the plurality of trench structures 35 for the monitor transistor 13.

Each authentic bump 90 may face 10 or more and 200 or less trench structures 35. The number of facing trench structures 35 according to each authentic bump 90 may be 10 or more and 25 or less, 25 or more and 50 or less, 50 or more and 75 or less, 75 or more and 100 or less, 100 or more and 125 or less, 125 or more and 150 or less, 150 or more and 175 or less, or 175 or more and 200 or less. The number of facing trench structures 35 according to each authentic bump 90 is preferably 25 or more and 100 or less.

Hereinafter, a specific shape of one authentic bump 90 will be described with reference to FIGS. 12 and 14. In this embodiment, the authentic bump 90 includes a second bump body 97 and a second bump metal film 98. The second bump body 97 contains a first metal. The first metal is made of a material different from the source terminal 26, and is preferably made of a metal harder than the source terminal 26. The first metal includes, for example, at least one of a Cu-based metal, an Al-based metal, an Au-based metal, and an Ag-based metal.

The Cu-based metal may contain pure Cu or a Cu alloy. The Al-based metal may contain pure Al or an Al alloy. The Au-based metal may contain pure Au or an Au alloy. The Ag-based metal may contain pure Ag or an Ag alloy. In this embodiment, the second bump body 97 contains pure Cu. In this case, the source terminal 26 is preferably an Al-based metal layer. The second bump body 97 preferably contains the same metal as the first bump body 77 of the pseudo bump 75. As a matter of course, the second bump body 97 may contain metal different from that of the first bump body 77.

The second bump body 97 includes a second body portion 99 and a second neck portion 100. The second body portion 99 is formed as a wide portion connected to the source terminal 26. The second body portion 99 is formed in a substantially columnar shape having a side wall curved outward in a cross-sectional view. The second body portion 99 has a second body size SB2 that forms the second size S2 of the authentic bump 90 in a plan view.

The second body portion 99 may have a second body thickness TB2 that is 0.1 times or more and 0.9 times or less the second thickness T2 of the authentic bump 90. The second body thickness TB2 is preferably larger than the thickness of the first semiconductor region 31. The second body thickness TB2 may be larger than the thickness of the substrate 2. As a matter of course, the second body thickness TB2 may be smaller than the thickness of the substrate 2.

The thickness ratio T2/TB2 of the second body thickness TB2 to the second thickness T2 may be 0.1 or more and 0.2 or less, 0.2 or more and 0.3 or less, 0.3 or more and 0.4 or less, 0.4 or more and 0.5 or less, 0.5 or more and 0.6 or less, 0.6 or more and 0.7 or less, 0.7 or more and 0.8 or less, or 0.8 or more and 0.9 or less. The thickness ratio T2/TB2 is preferably 0.4 or more and 0.7 or less. The thickness ratio T2/TB2 is particularly preferably 0.5 or more. The second body thickness TB2 may be approximately equal to the first body thickness TB1 of the pseudo bump 75.

The second neck portion 100 is formed as a portion protruding from the second body portion 99 toward the side opposite to the source terminal 26 to be narrower than the second body portion 99. The second neck portion 100 is formed in a substantially columnar shape in a cross-sectional view. The second neck portion 100 has a second upper end portion 101 connected to the wire loop 91. Unlike the first upper end portion 81 of the first neck portion 80, the second upper end portion 101 does not have the upper end top portion 82, the upper end base portion 83, and the inclined portion 84.

The second neck portion 100 has a second neck size SN2 smaller than the second body size SB2 in a plan view. The second neck size SN2 may be 0.1 times or more and 0.9 times or less the second body size SB2 (first size S1).

The size ratio SN2/SB2 of the second neck size SN2 to the second body size SB2 may be 0.1 or more and 0.2 or less, 0.2 or more and 0.3 or less, 0.3 or more and 0.4 or less, 0.4 or more and 0.5 or less, 0.5 or more and 0.6 or less, 0.6 or more and 0.7 or less, 0.7 or more and 0.8 or less, or 0.8 or more and 0.9 or less. The size ratio SN2/SB2 is preferably 0.5 or more and 0.7 or less. The size ratio SN2/SB2 is particularly preferably larger than 0.5. The second neck size SN2 may be substantially equal to the first neck size SN1 of the pseudo bump 75.

The second bump metal film 98 includes a second metal different from the first metal of the second bump body 97 and covers at least a part of the outer surface of the second bump body 97. The second bump metal film 98 also covers at least a part of the outer surface of the wire loop 91 and at least a part of the outer surface of the wire tail 92.

FIG. 14 illustrates a form in which the second bump metal film 98 covers the entire outer surface of the second bump body 97, but the second bump metal film 98 does not necessarily have such a form. Also, the form of the second bump metal film 98 between the plurality of authentic bumps 90 is indefinite, and is not fixed to a certain form.

For example, the second bump metal film 98 may cover at least a part of the outer surface of the second bump body 97 so as to partially expose the second bump body 97 (first metal), and a part of the second bump metal film 98 may be located inside the second bump body 97.

For example, a part of the second bump metal film 98 may be dissolved in the second bump body 97. For example, the covering area of the second bump metal film 98 with respect to the second bump body 97 may be smaller than the exposed area of the second bump body 97 with respect to the second bump metal film 98. As a matter of course, the covering area of the second bump metal film 98 with respect to the second bump body 97 may be equal to or larger than the exposed area of the second bump body 97 with respect to the second bump metal film 98.

The second bump metal film 98 is preferably made of a plating film. The second bump metal film 98 preferably includes at least one of an Ni plating film, a Pd plating film, and an Au plating film. For example, the second bump metal film 98 may have a laminated structure including an Ni plating film, a Pd plating film, and an Au plating film laminated in this order from the second bump body 97.

For example, the second bump metal film 98 may have a laminated structure including an Ni plating film and a Pd plating film laminated in this order from the second bump body 97. For example, the second bump metal film 98 may have a single-layer structure made of an Ni plating film, a Pd plating film, or an Au plating film. The second bump metal film 98 preferably has the same configuration as the first bump metal film 78 of the pseudo bump 75.

Referring to FIGS. 13 and 14, the semiconductor device 61 includes a plurality of first thin film portions 111, a plurality of second thin film portions 112, and a thick film portion 113 formed on the source terminal 26. Each of the plurality of first thin film portions 111 is formed as a portion where a part of the source terminal 26 sinks along with the bonding of the plurality of pseudo bumps 75, and is formed at each bonding portion of the plurality of pseudo bumps 75 in the source terminal 26.

Each of the plurality of second thin film portions 112 is formed as a portion where a part of the source terminal 26 sinks along with the bonding of the plurality of authentic bumps 90, and is formed at each bonding portion of the plurality of authentic bumps 90 in the source terminal 26. The thick film portion 113 is formed as a portion that does not sink due to the bonding of the plurality of pseudo bumps 75 and the plurality of authentic bumps 90, and is formed in a region outside the bonding portion of the plurality of pseudo bumps 75 and the bonding portion of the plurality of authentic bumps 90 in the source terminal 26.

The maximum thickness of the thick film portion 113 may be larger than the minimum thickness of the first thin film portion 111 (second thin film portion 112) and 2.5 times or less the minimum thickness of the first thin film portion 111 (second thin film portion 112). The thickness ratio of the maximum thickness to the minimum thickness may be larger than 1 and 1.25 or less, 1.25 or more and 1.5 or less, 1.5 or more and 1.75 or less, 1.75 or more and 2 or less, 2 or more and 2.25 or less, or 2.25 or more and 2.5 or less.

The semiconductor device 61 includes a plurality of first bulged portions 114 formed on the source terminal 26. The plurality of first bulged portions 114 are formed at bonding edge portions of the plurality of pseudo bumps 75 in the source terminal 26, and a part of the source terminal 26 is formed in a portion further thicker than the thick film portion 113. Each first bulged portion 114 annularly extends along an edge portion (bonding edge portion) of each pseudo bump 75 in a plan view. At least a part of each first bulged portion 114 faces the peripheral edge portion of each pseudo bump 75 in the thickness direction.

A portion of the source terminal 26 along the edge portion of each of the pseudo bumps 75 is thicker than the first thin film portion 111 by the thick film portion 113 and the plurality of first bulged portions 114. Also, a portion of the source terminal 26 located between the plurality of pseudo bumps 75 is thicker than the plurality of first thin film portions 111 by the thick film portion 113 and the first bulged portion 114.

A portion of the source terminal 26 located between the plurality of pseudo bumps 75 preferably faces the plurality of trench structures 35. That is, in the region between the plurality of pseudo bumps 75, it is preferable that the thick film portion 113 and the plurality of first bulged portions 114 face the plurality of trench structures 35.

The semiconductor device 61 includes the plurality of second bulged portions 115 formed on the source terminal 26. The plurality of second bulged portions 115 are formed at bonding edge portions of the plurality of authentic bumps 90 in the source terminal 26, and a part of the source terminal 26 includes a portion further thicker than the thick film portion 113. Each of the second bulged portions 115 annularly extends along an edge portion (bonding edge portion) of each of the authentic bumps 90 in a plan view. At least a part of each second bulged portion 115 faces the peripheral edge portion of each authentic bump 90 in the thickness direction.

A portion of the source terminal 26 along the edge portion of each authentic bump 90 is thicker than the second thin film portion 112 by the thick film portion 113 and the second bulged portion 115. Furthermore, a portion of the source terminal 26 located between the plurality of authentic bumps 90 is thicker than the second thin film portion 112 by the thick film portion 113 and the plurality of second bulged portions 115. Furthermore, a portion of the source terminal 26 located between the pseudo bump 75 and the authentic bump 90 is thickened by the thick film portion 113 and the plurality of second bulged portions 115. At least a part of each second bulged portion 115 faces the peripheral edge portion of each authentic bump 90 in the thickness direction.

The semiconductor device 61 includes at least one (in this embodiment, a plurality of) second bonding wires 119 disposed in the package body 62. The plurality of second bonding wires 119 electrically connect the first to fourth control terminals 27 to 30 to at least one connection target (in this embodiment, the fifth to eighth lead terminals 71E to 71H) selected from the first to eighth lead terminals 71A to 71H.

The number of the second bonding wires 119 for the first to fourth control terminals 27 to 30 may be one or more, and is not limited to a specific number. In this embodiment, one second bonding wire 119 is connected to the first control terminal 27 and the fifth lead terminal 71E, one second bonding wire 119 is connected to the second control terminal 28 and the sixth lead terminal 71F, one second bonding wire 119 is connected to the third control terminal 29 and the seventh lead terminal 71G, and one second bonding wire 119 is connected to the fourth control terminal 30 and the eighth lead terminal 71H.

Similarly to the first bonding wire 89, each of the plurality of second bonding wires 119 includes the authentic bump 90, the wire loop 91, and the wire tail 92. Also, similarly to the first bonding wire 89, the plurality of second bonding wires 119 include the second bump body 97 and the second bump metal film 98 in the authentic bump 90.

Preferably, the authentic bump 90 is bonded to the first to fourth control terminals 27 to 30, and the wire tail 92 is bonded to the fifth to eighth lead terminals 71E to 71H. As a matter of course, the authentic bump 90 may be bonded to the fifth to eighth lead terminals 71E to 71H, and the wire tail 92 may be bonded to the first to fourth control terminals 27 to 30. Other descriptions of the second bonding wire 119 will be omitted assuming that the description of the first bonding wire 89 is applied.

As described above, the semiconductor device 61 includes the substrate 2, the output region 6 (device region), the source terminal 26 (terminal), the plurality of pseudo bumps 75, and at least one authentic bump 90. The output region 6 is provided on the substrate 2. The source terminal 26 covers the output region 6 in a plan view. The plurality of pseudo bumps 75 are densely arranged on the source terminal 26 in a state of being released from the wire. At least one authentic bump 90 is disposed more sparsely on the source terminal 26 than the plurality of pseudo bumps 75 in a state of being connected to the wire.

That is, the plurality of pseudo bumps 75 are arranged on the source terminal 26 with a first occupied area per unit planar area, and at least one authentic bump 90 is disposed on the source terminal 26 with a second occupied area smaller than the first occupied area per unit planar area. According to this configuration, the heat generated in the output region 6 can be absorbed by the plurality of pseudo bumps 75. Thereby, a temperature rise in the output region 6 can be suppressed, and a decrease in electrical characteristics of the output region 6 due to the temperature rise can be suppressed. Therefore, it is possible to provide the semiconductor device 61 capable of improving electrical characteristics.

The arrangement position of the plurality of pseudo bumps 75 with respect to the source terminal 26 may be set based on the temperature distribution of the semiconductor chip 1. For example, the high temperature region and the low temperature region of the output region 6 are analyzed using thermography, a simulation tool, or the like, and the plurality of pseudo bumps 75 may be densely arranged in a portion of the source terminal 26 covering the high temperature region of the output region 6, and the plurality of pseudo bumps 75 may be sparsely arranged in a portion of the source terminal 26 covering the low temperature region of the output region 6. At least one authentic bump 90 is disposed in a portion where the plurality of pseudo bumps 75 are sparsely arranged.

For example, the inner portion of the output region 6 is likely to have a higher temperature than the peripheral edge portion of the output region 6. Therefore, the plurality of pseudo bumps 75 may be bonded to the source terminal 26 in a layout that is dense at the inner portion of the source terminal 26 and sparse at the peripheral edge portion of the source terminal 26. The form in which the plurality of pseudo bumps 75 are “sparse” also includes a form in which the pseudo bump 75 does not exist.

As another means for absorbing heat generated in the device region, it is conceivable to form a relatively thick plating terminal film (for example, a Cu plating film of 10 μm or more and 25 μm or less) on the source terminal 26 at the wafer stage or as the source terminal 26.

In this case, not only cost increases due to equipment (a film forming apparatus, a plating solution, or the like) required for forming a plating terminal film, but also warpage occurs in the wafer due to the plating terminal film. The electrical characteristics and physical characteristics of the wafer decrease due to warpage of the wafer. For example, when a crack or a crystal defect occurs in the wafer due to warpage of the wafer, the electrical characteristics of the device region fluctuate. Furthermore, the warpage of the wafer also becomes an obstacle in the dicing step and the like.

On the other hand, the semiconductor device 61 can bond the plurality of pseudo bumps 75 to the semiconductor chip 1 in the packaging step of the semiconductor chip 1 after being divided from the wafer through the dicing step. Therefore, equipment necessary for forming a plated terminal film is not required. Also, since the warpage of the wafer at the wafer stage can be suppressed, the semiconductor chip 1 in which cracks and crystal defects are suppressed can be acquired. Furthermore, the relatively thick pseudo bump 75 can be formed using a relatively inexpensive wire bonding step used in the step of forming the authentic bump 90. Therefore, the electrical characteristics can be improved while suppressing the cost.

As a matter of course, the pseudo bump 75 may be bonded to a plated terminal film formed on the terminal (source terminal 26) or a plated terminal film formed as the terminal (source terminal 26). In this case, the heat absorption effect by the plurality of pseudo bumps 75 can be added to the heat absorption effect by the plating terminal film. However, it should be noted that, when the amount of heat that can be absorbed by the plating terminal film is already saturated, the benefit of bonding the plurality of pseudo bumps 75 to the plating terminal film is small.

The plurality of pseudo bumps 75 is preferably thicker than the source terminal 26. According to this configuration, the source terminal 26 can be thinned by forming the plurality of relatively thick pseudo bumps 75. Therefore, heat can be transferred to the plurality of pseudo bumps 75 via the relatively thin source terminal 26, and at the same time, the formation cost of the source terminal 26 can be suppressed.

For example, the source terminal 26 including a Cu-based metal film or an Al-based metal film and having a thickness of 1 μm or more and 10 μm or less can be adopted by adopting the plurality of relatively thick pseudo bumps 75. Since such a source terminal 26 can be formed by a sputtering method, it can be constituted by an electrode film other than a plating film.

It is preferable that the plurality of authentic bumps 90 are sparsely arranged on the source terminal 26. That is, it is preferable that the design rule of densely arranging the plurality of authentic bumps 90 is not imposed. According to this configuration, the plurality of authentic bumps 90 can be connected to appropriate positions of the source terminal 26. The plurality of pseudo bumps 75 may be disposed on the source terminal 26 at the first pitch P1. In this case, it is preferable that the plurality of authentic bumps 90 are arranged on the source terminal 26 at the second pitch P2 equal to or larger than the first pitch P1.

Preferably, at least three pseudo bumps 75 are densely arranged on the source terminal 26. It is preferable that at least three pseudo bumps 75 are arranged in a layout located at vertexes of an isosceles triangle in a plan view. In this case, the isosceles triangle is particularly preferably an equilateral triangle. According to these configurations, the plurality of pseudo bumps 75 can be appropriately densely arranged. Also, the heat generated in the output region 6 can be absorbed by the pseudo bump group 76 including the plurality of pseudo bumps 75.

Preferably, at least seven pseudo bumps 75 are densely arranged on the source terminal 26. In this case, it is preferable that six pseudo bumps 75 (peripheral bumps 74) are arranged around one pseudo bump 75 (center bump 73). The six peripheral bumps 74 are preferably arranged on concentric circles centered on the center portion of one center bump 73 in a plan view. It is preferable that the six peripheral bumps 74 are arranged in a layout located at vertexes of the hexagon in a plan view, and one center bump 73 is arranged in a layout located at the center of the hexagon in a plan view.

That is, it is preferable that the plurality of pseudo bumps 75 are bonded to the source terminal 26 in a layout that is a hexagonal close-packed array (that is, a honeycomb array) in a plan view. In this case, the hexagon is particularly preferably a regular hexagon. According to these configurations, the plurality of pseudo bumps 75 can be appropriately densely arranged. Also, the heat generated in the output region 6 can be absorbed by the pseudo bump group 76 including the plurality of pseudo bumps 75.

The semiconductor device 61 preferably includes the first thin film portion 111 formed at the bonding portion of the pseudo bump 75 in the source terminal 26. According to this configuration, the heat generated in the output region 6 can be transferred to the pseudo bump 75 via the first thin film portion 111. The semiconductor device 61 preferably includes the thick film portion 113 formed in a region outside the bonding portion of the pseudo bump 75 in the source terminal 26. According to this configuration, the heat generated in the output region 6 can be absorbed by the thick film portion 113 in the region outside the bonding portion of the pseudo bump 75. The heat absorbed by the thick film portion 113 is transmitted to the pseudo bump 75.

Also, a portion of the source terminal 26 located between the plurality of pseudo bumps 75 is made thicker by the thick film portion 113 than the plurality of first thin film portions 111. According to these configurations, the heat generated in the output region 6 can be absorbed by the thick film portion 113 in the region outside the bonding portion of the pseudo bump 75.

The pseudo bump 75 may include the first bump body 77 containing the first metal and the first bump metal film 78 containing the second metal different from the first metal and covering at least a part of the outer surface of the first bump body 77. The pseudo bump 75 may include the wide first body portion 79 connected to the source terminal 26 and the first neck portion 80 protruding from the first body portion 79 toward the side opposite to the source terminal 26 to be narrower than the first body portion 79.

The semiconductor device 61 may include the plurality of trench structures 35 formed on the first principal surface 3 of the output region 6. In this case, the pseudo bump 75 preferably overlaps the plurality of trench structures 35 in a plan view. According to this configuration, the heat generated in the vicinity of the plurality of trench structures 35 and/or on the plurality of trench structures 35 can be absorbed by the pseudo bump 75 directly above the trench structures.

The pseudo bump 75 preferably has a thickness larger than the depth of each trench structure 35.

The semiconductor device 61 preferably includes the insulated gate type main transistor 11 including the plurality of trench structures 35 in the output region 6. According to this configuration, the temperature rise caused by the counter electromotive force of the inductive load L during the active clamping operation of the main transistor 11 can be suppressed by the plurality of pseudo bumps 75. Thereby, the active clamp resistance can be improved.

The main transistor 11 is preferably an n-system gate division transistor including n first gates FG to which n gate signals are individually input. According to this configuration, the main transistor 11 is controlled to switch between a full-on state in which all the first gates FG are in an on state, a part-on state in which some of the first gates FG are in an on state (some of the gates are in an off state), and a full-off state in which all the first gates FG are in an off state. In the main transistor 11, the on-resistance value in the part-on state is higher than the on-resistance value in the full-on state.

According to the n-system main transistor 11, the output voltage of the main transistor 11 can be clamped by controlling some of the first gates FG of the main transistor 11 to an on state and controlling some of the first gates FG of the main transistor 11 to an off state during the active clamping operation. Thereby, the main transistor 11 can be protected from the counter electromotive force of the inductive load L, and the active clamp tolerance can be improved.

The semiconductor device 61 preferably includes the control region 8 provided on the first principal surface 3. The semiconductor device 61 preferably includes a control circuit 17 formed in the control region 8 to generate a gate signal applied to the plurality of trench structures 35. In this case, the source terminal 26 preferably covers the output region 6 so as to expose the control region 8 in a plan view.

The semiconductor device 61 preferably includes the first temperature detecting region 9 provided on the first principal surface 3 so as to be adjacent to the output region 6, and the second temperature detecting region 10 provided on the first principal surface 3 so as to be adjacent to the control region 8. The semiconductor device 61 preferably includes the first temperature-sensitive diode 15 (first temperature sensor) formed in the first temperature detecting region 9 so as to detect the temperature of the output region 6, and the second temperature-sensitive diode 16 (second temperature sensor) formed in the second temperature detecting region 10 so as to detect the temperature of the control region 8.

In this case, the control circuit 17 may be configured to generate a gate signal based on the first temperature detecting signal ST1 (electric signal) from the first temperature-sensitive diode 15 and the second temperature detecting signal ST2 (electric signal) from the second temperature-sensitive diode 16. According to this configuration, the temperature rise in the output region 6 can be suppressed by the plurality of pseudo bumps 75, and at the same time, the temperature rise in the output region 6 can be suppressed using the control of the control circuit 17.

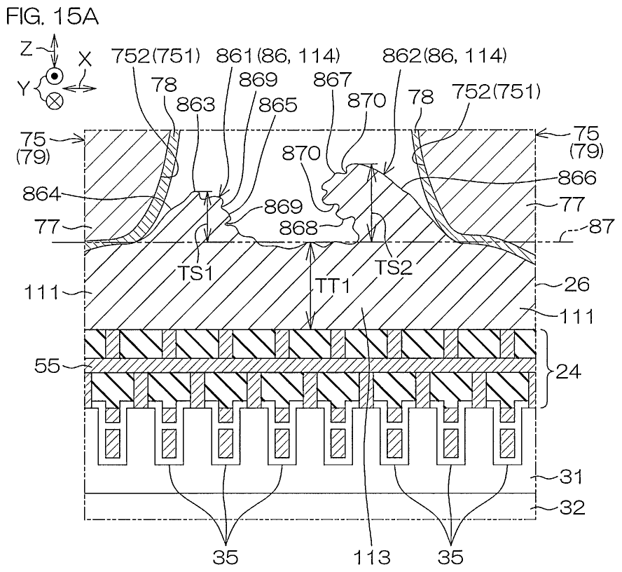

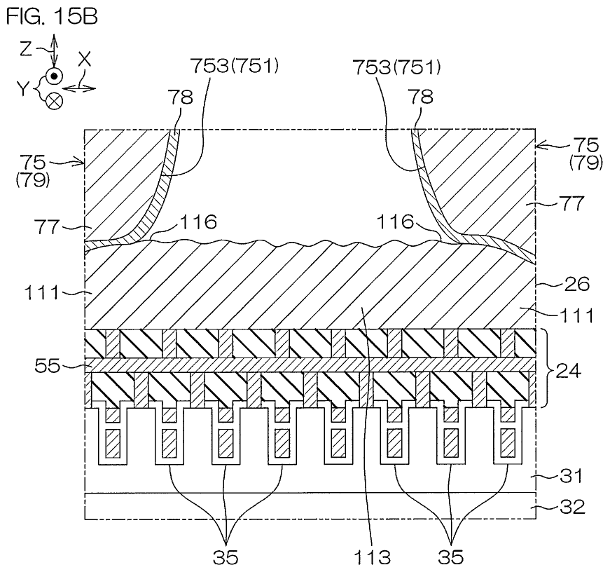

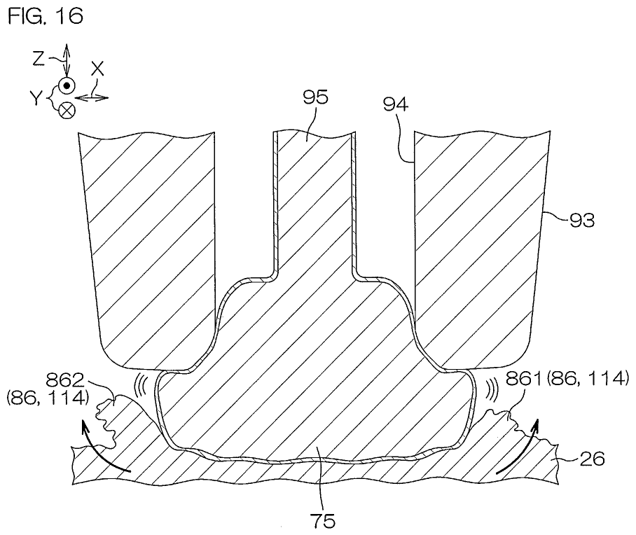

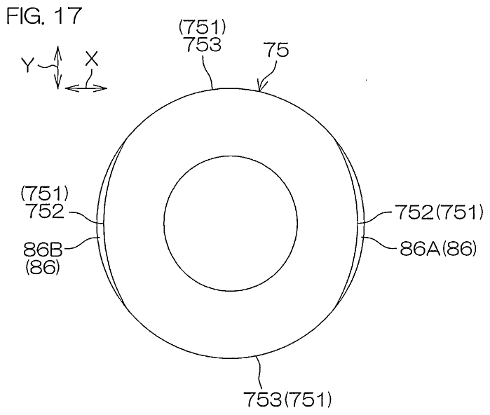

FIG. 15A is an enlarged view of a portion surrounded by an alternate long and two short dashed line XV in FIG. 13. FIG. 15B is a cross-sectional view of the pseudo bump 75 cut along the second direction Y. FIG. 16 is a bonding method diagram of the pseudo bump 75 to the source terminal 26. FIG. 17 is an enlarged view of the pseudo bump 75 in a plan view. FIGS. 15A and 15B to 17 illustrate the structure of the first bulged portion 114 of the pseudo bump 75, but the second bulged portion 115 of the authentic bump 90 has a similar structure.

Referring to FIGS. 15A and 15B, as described above, the first bulged portion 114 is formed on the source terminal 26. The first bulged portion 114 is a portion where a part of the source terminal 26 is thicker than the thick film portion 113 at the bonding edge portion of the pseudo bump 75. The first bulged portion 114 is formed by discharging a part of the source terminal 26 to the outside of the pseudo bump 75 from the lower portion to the side portion of each of the pseudo bumps 75 at the time of bonding the pseudo bump 75. Therefore, the first bulged portion 114 may be referred to as an extra material 86 of the source terminal 26. For example, the first bulged portion 114 may be referred to as a splash because a part of the source terminal 26 is splashed up around the pseudo bump 75.

A process of forming the extra material 86 will be described with reference to FIG. 16. A wire 95 is supplied to an inner hole 94 of a capillary 93, and an initial ball is formed at the distal end portion of the capillary 93 by electrical discharge machining on the wire 95. Next, the initial ball abuts on the source terminal 26, a load toward the source terminal 26 is applied to the initial ball, and at the same time, ultrasonic vibration is applied to the initial ball. The ultrasonic vibration is applied so as to have directivity in a specific direction. In this embodiment, ultrasonic vibration is selectively applied along the first direction X. Thereby, the initial ball is crushed and crimped to the source terminal 26 at the same time. A portion of the source terminal 26 pressed against the initial ball is pushed out from the lower portion of the initial ball to the outside by ultrasonic vibration along the first direction X, thereby forming the extra material 86. Thereafter, the wire is separated from the collapsed initial ball, and the pseudo bump 75 is formed.

As described above, the extra material 86 has a structure formed by pushing out a part of the source terminal 26 by ultrasonic vibration, and is not defined in a certain shape. Therefore, the extra material 86 around each of the pseudo bumps 75 may have various shapes. For example, the extra material 86 may include a first extra material 861 and a second extra material 862 having different shapes from each other.

Referring to FIG. 15A, the first extra material 861 may have a shape protruding in a mountain shape with respect to a base surface 87 set along the front surface of the thick film portion 113. The first extra material 861 may include a top portion 863, and a first inclined portion 864 (inner inclined portion) and a second inclined portion 865 (outer inclined portion) which are inclined downward at substantially the same angle from the top portion 863 toward the lower side and the opposite side of the pseudo bump 75 in a cross-sectional view. The second inclined portion 865 of the first extra material 861 extends toward the side portion of the pseudo bump 75 so as to be separated from the thick film portion 113. Thereby, the first extra material 861 is formed so as not to overlap above the thick film portion 113. A concave portion 869 may be selectively formed on the front surfaces of the first inclined portion 864 and the second inclined portion 865.

The second extra material 862 may have a shape warped upward with respect to the base surface 87. The second extra material 862 may include a first inclined portion 866 extending from the lower side of the pseudo bump 75 to the upper position of the thick film portion 113 and a second inclined portion 868 folded back at a distal end portion 867 of the first inclined portion 866 and extending toward the lower side of the pseudo bump 75 in a cross-sectional view. Since the distal end portion 867 of the second extra material 862 is located above the thick film portion 113, the second extra material 862 is formed so as to be spaced above the thick film portion 113 and overlap the thick film portion 113. A concave portion 870 may be selectively formed on the front surfaces of the first inclined portion 866 and the second inclined portion 868.

Compared to the thickness TT1 of the thick film portion 113, the first extra material 861 may have a first thickness TS1 smaller than the thickness TT1 and the second extra material 862 may have a second thickness TS2 larger than the thickness TT1. The second thickness TS2 may be larger than the first thickness TS1.

The first total thickness (TT1+TS1 or TT1+TS2) of the thick film portion 113 and the extra material 86 is preferably larger than the thickness of the interlayer insulating film 24. The first total thickness may be larger than 1 time the minimum thickness of the first thin film portion 111 and 10 times or less the minimum thickness of the first thin film portion 111. The thickness ratio of the first total thickness to the minimum thickness may be larger than 1 and 2 or less, 2 or more and 4 or less, 4 or more and 6 or less, 6 or more and 8 or less, or 8 or more and 10 or less. The thickness ratio is preferably 2 or more and 6 or less.

Referring to FIG. 17, since the extra material 86 is formed by ultrasonic vibration applied along the first direction X, it has directivity in the same direction as the application direction of the ultrasonic vibration. In this embodiment, the pair of extra materials 86 of the respective pseudo bumps 75 are formed on both sides of one side and the other side in the first direction X of the respective pseudo bumps 75 so as to have directivity along the first direction X in a plan view.

The pair of extra materials 86 may include a extra material 86A on one side and a extra material 86B on the other side in the first direction X. The extra material 86A and the extra material 86B are each formed in a curved shape in a plan view along the peripheral edge portion 751 of the pseudo bump 75 having a circular shape in a plan view. The extra material 86A and the extra material 86B may be formed in a crescent shape bulging toward opposite sides in the first direction X. The extra material 86A and the extra material 86B are physically independent of each other. Thereby, the peripheral edge portion 751 of the pseudo bump 75 may include a pair of arcuate first peripheral edge portions 752 adjacent to the extra material 86A and the extra material 86B in the first direction X, and a pair of arcuate second peripheral edge portions 753 between the end portion of the extra material 86A and the end portion of the extra material 86B. The first peripheral edge portion 752 may be a region covered with the extra material 86A and the extra material 86B in a plan view, and the second peripheral edge portion 753 may be a region not covered with the extra material 86A and the extra material 86B. Therefore, as illustrated in FIG. 15B, a flat region 116 including the thick film portion 113 is formed in the source terminal 26 below the second peripheral edge portion 753.

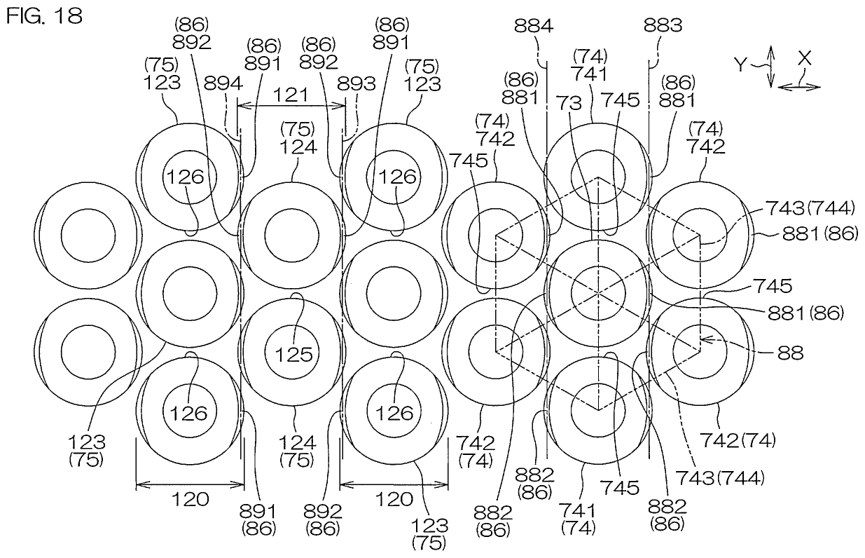

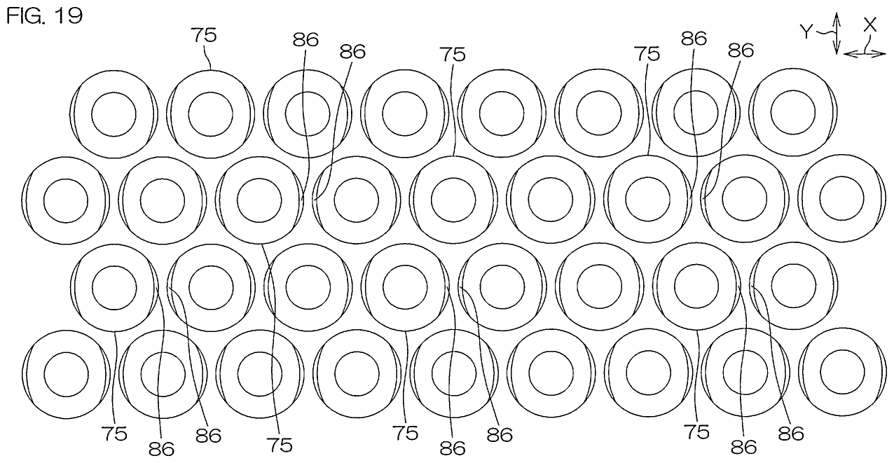

As described above, the extra material 86 is formed around the pseudo bump 75. The extra material 86 is formed outside the peripheral edge portion 751 of the pseudo bump 75. Therefore, when the plurality of pseudo bumps 75 are densely arranged as in the present disclosure and the distance between the adjacent pseudo bumps 75 decreases, the adjacent extra material 86 may interfere with each other. Therefore, a layout capable of avoiding interference of the extra material 86 will be described below with reference to FIGS. 18 and 19.

FIG. 18 is a plan view illustrating a first layout of the pseudo bump 75. FIG. 19 is a plan view illustrating a second layout of the pseudo bump 75.

Referring to FIGS. 18 and 19, in both the first layout and the second layout, at least three pseudo bumps 75 are arranged in a layout located at vertexes of a triangle in a plan view. Furthermore, when focusing on the seven pseudo bumps 75 adjacent to each other, the seven pseudo bumps 75 include one center bump 73 and six peripheral bumps 74 arranged on concentric circles centered on the center portion of the center bump 73 in a plan view. Thereby, the plurality of pseudo bumps 75 are arranged in a layout that is a hexagonal close-packed array (that is, a honeycomb array) in a plan view.

The first layout will be described in detail with reference to FIG. 18. The first layout may conceptually include an arrangement form of at least two patterns.

The first pattern is a honeycomb structure layout 88. The honeycomb structure layout 88 includes one center bump 73 and six peripheral bumps 74 arranged concentrically around a center portion of the center bump 73. Further, the peripheral bump 74 may include a first peripheral bump 741 and a second peripheral bump 742.

The first peripheral bump 741 includes two first peripheral bumps 741 adjacent to the center bump 73 in the second direction Y. The second peripheral bump 742 includes four second peripheral bumps 742 adjacent to the center bump 73 in an oblique direction inclined with respect to both the first direction X and the second direction Y. Two second peripheral bumps 742 are arranged on each of one side and the other side in the first direction X with respect to the center bump 73.

The honeycomb structure layout 88 includes a plurality of triangular layouts 743 in which the center bump 73 and the two second peripheral bumps 742 adjacent in the second direction Y are located at vertexes of a triangle in a plan view. In this embodiment, the honeycomb structure layout includes a triangular layout 743 that shares the center bump 73 with each other. An equilateral triangle is formed by a virtual line 744 connecting vertexes in each triangular layout 743.

The extra material 86 is formed on each of one side and the other side in the first direction X of the center bump 73 and each of the peripheral bumps 74. For example, the extra material 86 on one side in the first direction X of each center bump 73 and each peripheral bump 74 may be the first extra material 881, and the extra material 86 on the other side may be the second extra material 882.

In the honeycomb structure layout 88, the extra material 86 of the center bump 73 and the extra material 86 of the two first peripheral bumps 741 are arranged at intervals from each other along the second direction Y. More specifically, the first extra material 881 of the center bump 73 and the first extra material 881 of the two first peripheral bumps 741 are arranged at intervals from each other along the second direction Y. Similarly, the second extra material 882 of the center bump 73 and the second extra material 882 of the two first peripheral bumps 741 are arranged at intervals from each other along the second direction Y. The extra material 86 of the center bump 73 faces a space region 745 between the second peripheral bumps 742 in the first direction X.

In the honeycomb structure layout 88, the first extra material 881 of the center bump 73 and the second extra material 882 of the two second peripheral bumps 742 are arranged at intervals from each other along the second direction Y. Similarly, the second extra material 882 of the center bump 73 and the first extra material 881 of the two second peripheral bumps 742 are arranged at intervals from each other along the second direction Y.

Thereby, in the honeycomb structure layout 88, the first extra material 881 of the first peripheral bump 741, the second extra material 882 of the second peripheral bump 742, the first extra material 881 of the center bump 73, the second extra material 882 of the second peripheral bump 742, and the first extra material 881 of the first peripheral bump 741 are sequentially arranged along the second direction Y. In this embodiment, the first extra material 881 and the second extra material 882 are alternately arranged side by side on a virtual straight line 883 indicated by an alternate long and short dashed line in FIG. 18. The first extra material 881 and the second extra material 882 on the virtual straight line 883 overlap each other in the second direction Y.

Similarly, the second extra material 882 of the first peripheral bump 741, the first extra material 881 of the second peripheral bump 742, the second extra material 882 of the center bump 73, the first extra material 881 of the second peripheral bump 742, and the second extra material 882 of the first peripheral bump 741 are alternately arranged side by side on a virtual straight line 884 indicated by an alternate long and short dashed line in FIG. 18. The first extra material 881 and the second extra material 882 on the virtual straight line 884 overlap each other in the second direction Y.

As described above, in the honeycomb structure layout 88, the first extra material 881 and the second extra material 882 are alternately arranged side by side on the virtual straight lines 883 and 884 and overlap each other in the second direction Y. Although the extra material 86 (the first extra material 881 and the second extra material 882) is formed to have directivity in the first direction X, it is possible to prevent the plurality of extra materials 86 from interfering with each other by adopting the honeycomb structure layout 88 of FIG. 18. Thereby, for example, the space region 745 between the respective pseudo bumps 75 can be used as a space for releasing the extra material 86 of the adjacent pseudo bump 75. As a result, since the plurality of pseudo bumps 75 can be arranged in a dense layout, the number of pseudo bumps 75 can be increased to improve heat dissipation.

Next, the second pattern of the first layout includes a first line bump group 120 and a second line bump group 121 each including a plurality of pseudo bumps 75 arranged along the second direction Y. In FIG. 18, the first line bump group 120 includes three pseudo bumps 75, and the second line bump group 121 includes two pseudo bumps 75. The first line bump group 120 and the second line bump group 121 are alternately arranged in the first direction X.

The plurality of pseudo bumps 75 of the first line bump group 120 may be referred to as a first pseudo bump 123, and the plurality of pseudo bumps 75 of the second line bump group 121 may be referred to as a second pseudo bump 124. The first pseudo bump 123 faces the space region 125 between two second pseudo bumps 124 in the first direction X. Thereby, in the pair of first line bump groups 120 adjacent to each other in the first direction X with the second line bump group 121 interposed therebetween, the extra material 86 of the pseudo bump 75 of one first line bump group 120 and the extra material 86 of the pseudo bump 75 of the other first line bump group 120 face each other via the space region 125 between the plurality of pseudo bumps 75 in the second line bump group 121 in a plan view.

On the other hand, the second pseudo bump 124 faces the space region 126 between two first pseudo bumps 123 in the first direction X.

The extra material 86 is formed on each of one side and the other side in the first direction X of the first pseudo bump 123 and the second pseudo bump 124. For example, the extra material 86 on one side in the first direction X of each first pseudo bump 123 and each second pseudo bump 124 may be a first extra material 891, and the extra material 86 on the other side may be a second extra material 892.

In the second pattern, the first extra material 891 of the first pseudo bump 123 and the second extra material 892 of the second pseudo bump 124 are alternately arranged at intervals from each other along the second direction Y. Similarly, the second extra material 892 of the first pseudo bump 123 and the first extra material 891 of the second pseudo bump 124 are alternately arranged at intervals from each other along the second direction Y. Thereby, the first extra material 891 and the second extra material 892 are alternately arranged side by side on virtual straight lines 893 and 894 indicated by an alternate long and short dashed line in FIG. 18. The first extra material 891 and the second extra material 892 on the virtual straight lines 893 and 894 overlap each other in the second direction Y.

As described above, in the second pattern, the first extra material 891 and the second extra material 892 are alternately arranged side by side on the virtual straight lines 893 and 894 and overlap each other in the second direction Y. Although the extra material 86 (the first extra material 891 and the second extra material 892) is formed to have directivity in the first direction X, it is possible to prevent the plurality of extra materials 86 from interfering with each other by adopting the layout of the second pattern in FIG. 18. Thereby, for example, the space regions 125 and 126 between the respective pseudo bumps 75 can be used as a space for releasing the extra material 86 of the adjacent pseudo bumps 75. As a result, since the plurality of pseudo bumps 75 can be arranged in a dense layout, the number of pseudo bumps 75 can be increased to improve heat dissipation.

On the other hand, in the layout of FIG. 19, the pseudo bumps 75 are arranged in the same row along the direction (in this embodiment, the first direction X) in which the ultrasonic vibration is applied by the capillary 93 (see FIG. 16). Therefore, the extra materials 86 may overlap and interfere with each other in the first direction X. As a result, it is difficult to arrange the plurality of pseudo bumps 75 in a dense layout as compared with the layout of FIG. 18.

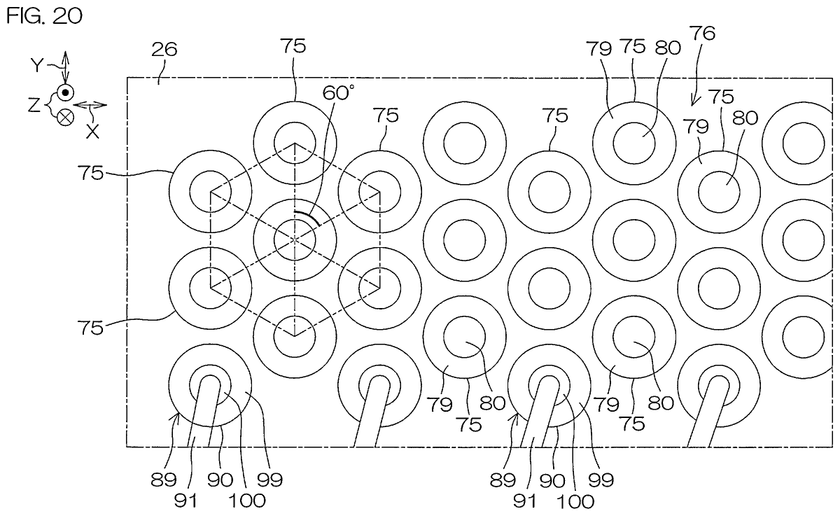

FIG. 20 is a plan view illustrating a modified example of the layout in FIG. 12.

In the preferred embodiment described above, a layout in which only the plurality of pseudo bumps 75 form a hexagonal close-packed array (that is, a honeycomb array) is configured. On the other hand, as illustrated in FIG. 20, in a form in which at least one authentic bump 90 is included in the plurality of pseudo bumps 75, a layout having a hexagonal close-packed array (that is, a honeycomb array) in a plan view may be configured.

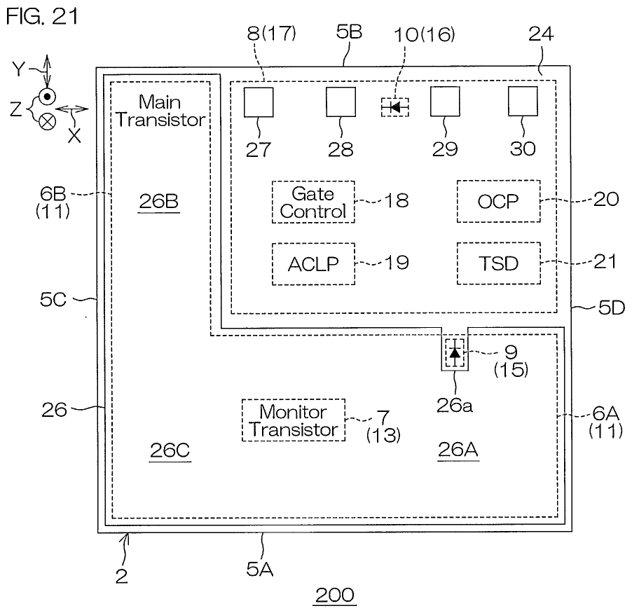

FIG. 21 is a plan view illustrating a semiconductor chip 200 according to a second configuration example.

Referring to FIG. 21, the semiconductor chip 200 has a form in which the layout of the output region 6 of the semiconductor chip 1 is changed. In this embodiment, the output region 6 is partitioned into an L shape in a plan view. Specifically, the output region 6 includes a first region 6A extending in a band shape along the first direction X in a region on the first side surface 5A side, and a second region 6B extending in a band shape along the second direction Y in a region on the third side surface 5C side.

In this embodiment, the control region 8 is provided in a region defined by the peripheral edge of the first principal surface 3, the first region 6A of the output region 6, and the second region 6B of the output region 6 in the region on the second side surface 5B side. The current detecting region 7 may be provided in any one or both of the first region 6A of the output region 6 and the second region 6B of the output region 6. In this embodiment, the current detecting region 7 is provided in the first region 6A.

The first temperature detecting region 9 may be provided so as to be adjacent to one or both of the first region 6A of the output region 6 and the second region 6B of the output region 6. In this embodiment, the first temperature detecting region 9 is provided so as to be adjacent to the first region 6A. As in the case of the first configuration example, the second temperature detecting region 10 is provided adjacent to the control region 8.

In this embodiment, the source terminal 26 is partitioned into an L shape in a plan view. Specifically, the source terminal 26 includes a first terminal portion 26A extending in a band shape along the first direction X so as to cover the first region 6A of the output region 6, and a second terminal portion 26B extending in a band shape along the second direction Y so as to cover the second region 6B of the output region 6. In this embodiment, the source terminal 26 has a cutout portion 26a cut out in a quadrangular shape so as to expose the first temperature detecting region 9 in the first terminal portion 26A.

The first to fourth control terminals 27 to 30 are arranged in a region defined by the peripheral edge of the first principal surface 3, the first terminal portion 26A of the source terminal 26, and the second terminal portion 26B of the source terminal 26 in the region on the second side surface 5B side.

Thus, the preferred embodiments of the present disclosure in all respects are illustrative and not to be interpreted to be restrictive and are intended to include modifications in all respects. The following appended features can be extracted from the descriptions in this Description and the drawings.

### Appendix 1-1

A semiconductor device (61) including:
a substrate (2);
a device region (6) provided on the substrate (2);
a terminal (26) covering the device region (6) in a plan view; and
a plurality of pseudo bumps (75) arranged on the terminal (26),
wherein the plurality of pseudo bumps (75) include at least three pseudo bumps (75) densely arranged in a layout located at vertexes of a triangle in a plan view,
an extra material (86) is formed by bulging of a part of the terminal (26) from a lower portion to a side portion of each of the three pseudo bumps (75),
a pair of the extra materials (86) of each of the pseudo bumps (75) are formed on both sides of one side and the other side in a first direction (X) of each of the pseudo bumps (75) so as to have directivity along the first direction (X) in a plan view, and
the extra materials (86) of the three pseudo bumps (75) are arranged at intervals from each other along a second direction (Y) orthogonal to the first direction (X).

According to this configuration, the extra materials (86) of at least three pseudo bumps (75) are arranged at intervals from each other along the second direction (Y). Therefore, although the plurality of extra materials (86) are each formed to have directivity in the first direction (X), it is possible to prevent the plurality of extra materials (86) from interfering with each other. As a result, since the plurality of pseudo bumps (75) can be arranged in a dense layout, the number of pseudo bumps (75) can be increased to improve heat dissipation.

### Appendix 1-2

The semiconductor device (61) according to Appendix 1-1,
wherein when focusing on the two pseudo bumps (75) adjacent to each other in an oblique direction inclined with respect to both the first direction (X) and the second direction (Y) in a plan view, the extra material (86) on a side closer to the other pseudo bump (75) in the pair of extra materials (86) of one pseudo bump (75) and the extra material (86) on a side closer to the one pseudo bump (75) in the pair of extra materials (86) of the other pseudo bump (75) overlap each other in the second direction (Y).

### Appendix 1-3

The semiconductor device (61) according to Appendix 1-1 or Appendix 1-2,
wherein the terminal (26) includes a flat region (116) where the extra material (86) is not formed between the extra material (86) on one side and the extra material (86) on the other side in the first direction (X) of each of the pseudo bumps (75).

### Appendix 1-4

A semiconductor device (61) including:
a substrate (2);
a device region (6) provided on the substrate (2);
a terminal (26) covering the device region (6) in a plan view; and
a plurality of pseudo bumps (75) arranged on the terminal (26),
wherein the plurality of pseudo bumps (75) are arranged in a honeycomb structure layout (88) including one center bump (73) and six peripheral bumps (74) densely arranged in a layout located at vertexes of a hexagon in a plan view around the center bump (73),
a extra material (86) is formed by bulging of a part of the terminal (26) from a lower portion to a side portion of each of the plurality of pseudo bumps (75),
a pair of the extra materials (86) of each of the pseudo bumps (75) are formed on both sides of one side and the other side in a first direction (X) of each of the pseudo bumps (75) so as to have directivity along the first direction (X) in a plan view, and
the extra material (86) of the center bump (73) and the extra materials (86) of two first peripheral bumps (741) adjacent to the center bump (73) in a second direction (Y) orthogonal to the first direction (X) among the plurality of peripheral bumps (74) are arranged at intervals from each other along the second direction (Y).

According to this configuration, the extra material (86) of the center bump (73) and the extra material (86) of the two first peripheral bumps (741) are arranged at intervals from each other along the second direction (Y). Therefore, although the plurality of extra materials (86) are each formed to have directivity in the first direction (X), it is possible to prevent the plurality of extra materials (86) from interfering with each other. As a result, since the plurality of pseudo bumps (75) can be arranged in the dense honeycomb structure layout (88), the number of the pseudo bumps (75) can be increased to improve the heat dissipation.

### Appendix 1-5

The semiconductor device (61) according to Appendix 1-4,
wherein when focusing on the center bump (73) and two second peripheral bumps (742) adjacent to the center bump (73) in an oblique direction inclined with respect to both the first direction (X) and the second direction (Y) in a plan view, the extra material (86) of the center bump (73) faces a space region (745) between the second peripheral bumps (742) in the first direction (X).

### Appendix 1-6

The semiconductor device (61) according to Appendix 1-5,
wherein the extra material (86) of the first peripheral bump (741), the extra material (86) of the second peripheral bump (742), the extra material (86) of the center bump (73), the extra material (86) of the second peripheral bump (742), and the extra material (86) of the first peripheral bump (741) are sequentially arranged along the second direction (Y).

### Appendix 1-7

The semiconductor device (61) according to any one of Appendices 1-4 to 1-6,
wherein the honeycomb structure layout (88) includes a plurality of triangular layouts (743) in which two adjacent peripheral bumps (74) of the center bump (73) and the plurality of peripheral bumps (74) are located at vertexes of a triangle in a plan view, and
in each of the triangular layouts (743), an equilateral triangle is formed by a virtual line (744) connecting the vertexes.

### Appendix 1-8

A semiconductor device (61):
a substrate (2);
a device region (6) provided on the substrate (2);
a terminal (26) covering the device region (6) in a plan view; and
a plurality of pseudo bumps (75) arranged on the terminal (26),
wherein an extra material (86) is formed by bulging of a part of the terminal (26) from a lower portion to a side portion of each of the plurality of pseudo bumps (75),
a pair of the extra materials (86) of each of the pseudo bumps (75) are formed on both sides of one side and the other side in a first direction (X) of each of the pseudo bumps (75) so as to have directivity along the first direction (X) in a plan view, and
a first line bump group (120) and a second line bump group (121) each including the plurality of pseudo bumps (75) are arranged along a second direction (Y) orthogonal to the first direction (X),
the first line bump group (120) and the second line bump group (121) are alternately arranged in the first direction (X), and
the extra material (86) of the pseudo bump (75) of the first line bump group (120) and the extra material (86) of the pseudo bump (75) of the second line bump group (121) are alternately arranged at intervals from each other along the second direction (Y) between the first line bump group (120) and the second line bump group (121).

According to this configuration, the extra material (86) of the pseudo bump (75) of the first line bump group (120) and the extra material (86) of the pseudo bump (75) of the second line bump group (121) are arranged at intervals from each other along the second direction (Y). Therefore, although the plurality of extra materials (86) are each formed to have directivity in the first direction (X), it is possible to prevent the plurality of extra materials (86) from interfering with each other. As a result, since the plurality of pseudo bumps (75) can be arranged in a dense line layout, the number of pseudo bumps (75) can be increased to improve heat dissipation.

### Appendix 1-9

The semiconductor device (61) according to Appendix 1-8,
wherein in a pair of the first line bump groups (120) adjacent to each other in the first direction (X) with the second line bump group (121) interposed therebetween, the extra material (86) of the pseudo bump (75) of one first line bump group (61) and the extra material (86) of the pseudo bump (75) of the other first line bump group (120) face each other via a space region (125) between the plurality of pseudo bumps (75) in the second line bump group (121) in a plan view.

### Appendix 1-10

The semiconductor device (61) according to any one of Appendices 1-1 to 1-9,
wherein materials of the terminal (26) and the plurality of pseudo bumps (75) are different.

### Appendix 1-11

The semiconductor device (61) according to Appendix 1-10,
wherein the materials of the plurality of pseudo bumps (75) are harder than the material of the terminal (26).

### Appendix 1-12

The semiconductor device (61) according to Appendix 1-11,
wherein the plurality of pseudo bumps (75) are made of copper, and the terminal (26) is made of aluminum.

### Appendix 1-13

The semiconductor device (61) according to any one of Appendices 1-1 to 1-12,
wherein a pitch (P1) of the plurality of pseudo bumps (75) is 50 μm or more and 250 μm or less.

### Appendix 1-14

The semiconductor device (61) according to any one of Appendices 1-1 to 1-13, further including:
an authentic bump (90) disposed on the terminal (26) in a state of being connected to a wire (91).

### Appendix 1-15

The semiconductor device (61) according to Appendix 1-14,
wherein the authentic bump (90) is made of the same material as the plurality of pseudo bumps (75).

### Appendix 1-16

The semiconductor device (61) according to any one of Appendices 1-1 to 1-15, further including:
a plurality of trench structures (35) formed in the device region (6) in the substrate (2); and
a transistor (11) including the plurality of trench structures (35).

### Appendix 1-17

The semiconductor device (61) according to Appendix 1-16,
wherein the transistor (11) includes a plurality of system transistors that are individually controlled, and is a gate division transistor that generates a single output signal by selection control of the plurality of system transistors.

### Appendix 1-18

The semiconductor device (61) according to Appendix 1-17,
wherein the transistor (11) is configured such that on-resistance is changed by individual control of the plurality of system transistors.

### Appendix 1-19

The semiconductor device (61) according to any one of Appendices 1-1 to 1-18,
wherein the extra material (86) has a shape warped upward with respect to a front surface of the terminal (26).

### Appendix 1-20

The semiconductor device (61) according to Appendix 1-19,
wherein the extra material (86, 862) includes, in a cross-sectional view, a first inclined portion (866) extending from a lower side of the pseudo bump (75) to a position above a flat region (113, 116) of the terminal (26), and a second inclined portion (868) folded back at a distal end portion (867) of the first inclined portion (866) and extending toward a lower side of the pseudo bump (75), and
the extra material (86, 862) is spaced above the flat region (113, 116) of the terminal (26) and overlaps the flat region (113, 116).

According to this configuration, the extra material (86, 862) is warped upward so as to overlap the flat region (113, 116) of the terminal (26). Even in such a configuration, since the space between the adjacent pseudo bumps (75) can be used as a region where the extra material (86) overlaps, the space can be effectively used.

What is claimed is:

1. A semiconductor device comprising:
a substrate;
a device region provided on the substrate;
a terminal covering the device region in a plan view; and
a plurality of pseudo bumps arranged on the terminal,
wherein the plurality of pseudo bumps include at least three pseudo bumps densely arranged in a layout located at vertexes of a triangle in a plan view,
an extra material is formed by bulging of a part of the terminal from a lower portion to a side portion of each of the three pseudo bumps,
a pair of the extra materials of each of the pseudo bumps are formed on both sides of one side and the other side in a first direction of each of the pseudo bumps so as to have directivity along the first direction in a plan view, and
the extra materials of the three pseudo bumps are arranged at intervals from each other along a second direction orthogonal to the first direction.

2. The semiconductor device according to claim 1, wherein when focusing on the two pseudo bumps adjacent to each other in an oblique direction inclined with respect to both the first direction and the second direction in a plan view, the extra material on a side closer to the other pseudo bump in the pair of extra materials of the one pseudo bump and the extra material on a side closer to the one pseudo bump in the pair of extra materials of the other pseudo bump overlap each other in the second direction.

3. The semiconductor device according to claim 1, wherein the terminal includes a flat region where the extra material is not formed between the extra material on one side and the extra material on the other side in the first direction of each of the pseudo bumps.

4. A semiconductor device comprising:
a substrate;
a device region provided on the substrate;
a terminal covering the device region in a plan view; and
a plurality of pseudo bumps arranged on the terminal,
wherein the plurality of pseudo bumps are arranged in a honeycomb structure layout including one center bump and six peripheral bumps densely arranged in a layout located at vertexes of a hexagon in a plan view around the center bump,
an extra material is formed by bulging of a part of the terminal from a lower portion to a side portion of each of the plurality of pseudo bumps,
a pair of the extra materials of each of the pseudo bumps are formed on both sides of one side and the other side in a first direction of each of the pseudo bumps so as to have directivity along the first direction in a plan view, and
the extra material of the center bump and the extra material of two first peripheral bumps adjacent to the center bump in a second direction orthogonal to the first direction among the plurality of peripheral bumps are arranged at intervals from each other along the second direction.

5. The semiconductor device according to claim 4, wherein when focusing on the center bump and the two second peripheral bumps adjacent to the center bump in an oblique direction inclined with respect to both the first direction and the second direction in a plan view, the extra material of the center bump faces a space region between the second peripheral bumps in the first direction.

6. The semiconductor device according to claim 5, wherein the extra material of the first peripheral bump, the extra material of the second peripheral bump, the extra material of the center bump, the extra material of the second peripheral bump, and the extra material of the first peripheral bump are sequentially arranged along the second direction.

7. The semiconductor device according to claim 4,
wherein the honeycomb structure layout includes a plurality of triangular layouts in which two adjacent peripheral bumps of the center bump and the plurality of peripheral bumps are located at vertexes of a triangle in a plan view, and
in each of the triangular layouts, an equilateral triangle is formed by a virtual line connecting the vertexes.

8. A semiconductor device comprising:
a substrate;
a device region provided on the substrate;
a terminal covering the device region in a plan view; and
a plurality of pseudo bumps arranged on the terminal,
wherein an extra material is formed by bulging of a part of the terminal from a lower portion to a side portion of each of the plurality of pseudo bumps,
a pair of the extra materials of each of the pseudo bumps are formed on both sides of one side and the other side in a first direction of each of the pseudo bumps so as to have directivity along the first direction in a plan view,
a first line bump group and a second line bump group each including the plurality of pseudo bumps are arranged along a second direction orthogonal to the first direction,
the first line bump group and the second line bump group are alternately arranged in the first direction, and
the extra material of the pseudo bump of the first line bump group and the extra material of the pseudo bump of the second line bump group are alternately arranged at intervals from each other along the second direction between the first line bump group and the second line bump group.

9. The semiconductor device according to claim 8,
wherein in a pair of the first line bump groups adjacent to each other in the first direction with the second line bump group interposed therebetween,
the extra material of the pseudo bump of one of the first line bump groups and the extra material of the pseudo bump of the other first line bump group face each other via a space region between the plurality of pseudo bumps in the second line bump group in a plan view.

10. The semiconductor device according to claim 1, wherein materials of the terminal and the plurality of pseudo bumps are different.

11. The semiconductor device according to claim 10, wherein the materials of the plurality of pseudo bumps are harder than the material of the terminal.

12. The semiconductor device according to claim 11, wherein the plurality of pseudo bumps are made of copper, and the terminal is made of aluminum.

13. The semiconductor device according to claim 1, wherein a pitch of the plurality of pseudo bumps is 50 μm or more and 250 μm or less.

14. The semiconductor device according to claim 1, further comprising:
an authentic bump disposed on the terminal in a state of being connected to a wire.

15. The semiconductor device according to claim 14, wherein the authentic bump is made of
the same material as the plurality of pseudo bumps.
